(19) United States
(12) Patent Application Publication
(10) Pub. No.: US 2026/0013306 A1
(43) Pub. Date: Jan. 8, 2026

(54) DISPLAY DEVICE AND METHOD FOR MANUFACTURING THE SAME

(71) Applicant: SAMSUNG DISPLAY CO., LTD., YONGIN-SI (KR)

(72) Inventor: JAEHUN LEE, Yongin-si (KR)

(21) Appl. No.: 19/090,562

(22) Filed: Mar. 26, 2025

(30) Foreign Application Priority Data
Jul. 4, 2024 (KR) 10-2024-0087976

(51) Int. Cl. H10H 29/855; H01L 25/075; H01L 25/16; H10H 29/01; H10H 29/37; H10H 29/41

(52) U.S. Cl. CPC H10H 29/8552; H01L 25/167; H10H 29/012; H10H 29/032; H10H 29/37; H10H 29/41; H01L 25/0753

(57) ABSTRACT

A display device includes a circuit layer, a display element layer disposed on the circuit layer, and a light control layer disposed on the display element layer. The display element layer may include a first light-emitting element, a second light-emitting element spaced apart from the first light-emitting element in a first direction perpendicular to a thickness direction, a pixel-defining film having first and second pixel openings defined therein, and an organic layer disposed between the circuit layer and the pixel-defining film. The light control layer may include a transmission part having an opening defined therein, and a light blocking part disposed to fill the opening. The first light-emitting element may be disposed on a same layer as the organic layer, and the second light-emitting element may be disposed above the organic layer.

### CROSS-REFERENCE TO RELATED APPLICATIONS

This application claims priority under 35 U.S.C. § 119 to Korean Patent Application No. 10-2024-0087976, filed on Jul. 4, 2024 in the Korean Intellectual Property Office, the disclosure of which is incorporated by reference in its entirety herein.

### 1. TECHNICAL FIELD

The present disclosure herein relates to a display device including a light control layer which controls light having an exit angle greater than or equal to a predetermined angle, and a method for manufacturing the same.

### 2. DISCUSSION OF RELATED ART

Consumer demands for a display device for displaying images are becoming increasingly diverse along with the development of the information society. For example, a display device may be applied to various electronic apparatuses such as a smartphone, a digital camera, a laptop computer, a car navigation unit, and a smart television. Additionally, a display device may be applied to an instrument panel, a center fascia, or a center information display (CID) disposed on a dashboard in a car.

Such a display device may include a configuration for limiting an exit angle of light to increase security or reflection phenomenon, if necessary. However, research is being conducted to increase the display quality of a display device that includes a configuration for limiting an exit angle of light.

### SUMMARY

Embodiments of the present disclosure provides a display device with excellent display quality and a method for manufacturing the same.

According to an embodiment of the present inventive concept, an electronic device includes a display device. A power supply provides power to the display device. The display device comprises: a circuit layer including a transistor, and at least one insulating layer disposed on the transistor; a display element layer disposed on the circuit layer, the display element layer including a first light-emitting element having a first light-emitting layer, a second light-emitting element having a second light-emitting layer, the second light-emitting element is spaced apart from the first light-emitting element in a first direction perpendicular to a thickness direction of the display device, a pixel-defining film having a first pixel opening and a second pixel opening defined therein, and an organic layer disposed between the circuit layer and the pixel-defining film in the thickness direction of the display device; and a light control layer disposed on the display element layer, the light control layer including a transmission part having an opening defined therein, and a light blocking part disposed to fill the opening and blocking light emitted by the display element layer. The light blocking part overlaps the first light-emitting layer and does not overlap the second light-emitting layer. The first light-emitting element is co-planar with the organic layer. The second light-emitting element is disposed above the organic layer.

In an embodiment, the first light-emitting element is disposed directly above the circuit layer and the second light-emitting element is disposed directly above the organic layer.

In an embodiment, the organic layer may include: a first sub-organic layer; and a second sub-organic layer disposed on the first sub-organic layer.

In an embodiment, the first sub-organic layer may have a first organic opening defined therein, the second sub-organic layer may have a second organic opening defined therein, and the first organic opening and the second organic opening may each overlap the first pixel opening, and may not overlap the second pixel opening.

In an embodiment, a second width of the second organic opening may be greater than or equal to a first width of the first organic opening in the first direction.

In an embodiment, the organic layer includes a contact hole defined therein, the contact hole connecting the second light-emitting element and the transistor.

In an embodiment, the organic layer may include an organic material that is a same material as a material of the at least one insulating layer.

In an embodiment, in a first mode, the first light-emitting element may emit light and the second light-emitting element may not emit light, and in a second mode, the first light-emitting element may not emit light and the second light-emitting element may emit light.

In an embodiment, the light blocking part may overlap the first light-emitting layer, and may not overlap the second light-emitting layer.

In an embodiment, the light blocking part may include a first sub-light blocking part, and a second sub-light blocking part spaced apart from the first sub-light blocking part in the first direction, the first sub-light blocking part may overlap the pixel-defining film, the second sub-light blocking part may overlap the first light-emitting layer, and the first sub-light blocking part and the second sub-light blocking part may not overlap the second light-emitting layer.

In an embodiment, the first light-emitting element and the second light-emitting element may emit light having a same color as each other.

In an embodiment, the electronic device may be a television, a monitor, an outdoor billboard, a tablet computer, a vehicle navigation unit, a personal computer, a laptop computer, a personal digital terminal, a game console, a smart phone, or a camera.

According to an embodiment of the present inventive concept, an electronic device includes a display device. The display device includes a circuit layer including a transistor, and at least one insulating layer disposed on the transistor. A display element layer is disposed on the circuit layer, the display element layer including a first light-emitting element, a second light-emitting element spaced apart from the first light-emitting element in a first direction perpendicular to a thickness direction of the display device, a pixel-defining film having a first pixel opening and a second pixel opening defined therein, and an organic layer disposed between the circuit layer and the pixel-defining film in the thickness direction of the display device. A light control layer is disposed on the display element layer, the light control layer including a transmission part having an opening defined therein, and a light blocking part disposed to fill the opening. The first light-emitting element includes a first lower electrode exposed in the first pixel opening, a first upper electrode disposed on the first lower electrode, and a first light-emitting layer disposed between the first lower electrode and the first upper electrode. The second light-emitting element includes a second lower electrode exposed in the second pixel opening, a second upper electrode disposed on the second lower electrode, and a second light-emitting layer disposed between the second lower electrode and the second upper electrode. In the thickness direction of the display device, a first shortest distance from the circuit layer to the first light-emitting layer is less than a second shortest distance from the circuit layer to the second light-emitting layer.

In an embodiment, the first light-emitting element may be disposed on a same layer as the organic layer, and the second light-emitting element may be disposed above the organic layer.

In an embodiment, the organic layer may not overlap the first light-emitting layer and may overlap the second light-emitting layer.

In an embodiment, the organic layer may have an organic opening defined therein, and the organic opening may overlap the first pixel opening, and may not overlap the second pixel opening.

In an embodiment, the organic layer includes a contact hole defined therein, the contact hole connecting the second light-emitting element and the transistor.

In an embodiment, in a first mode, the first light-emitting element may emit light and the second light-emitting element may not emit light, and in a second mode, the first light-emitting element may not emit light and the second light-emitting element may emit light.

In an embodiment, the light blocking part may overlap the first light-emitting element, and may not overlap the second light-emitting element.

According to an embodiment of the present inventive concept, a method for manufacturing an electronic device comprises a method for manufacturing a display device. The method for manufacturing the display device includes preparing a circuit layer including a transistor and at least one insulating layer disposed on the transistor; forming a first lower electrode on the circuit layer; forming an organic layer on the circuit layer; forming a second lower electrode above the organic layer; forming a pixel-defining film having a first pixel opening and a second pixel opening defined therein, the first pixel opening exposing the first lower electrode and the second pixel opening exposing the second lower electrode; forming a first light-emitting layer on the first lower electrode, and forming a second light-emitting layer on the second lower electrode; forming a first upper electrode on the first light-emitting layer, and forming a second upper electrode on the second light-emitting layer; and forming, on the first upper electrode and the second upper electrode, a light control layer including a transmission part having an opening defined therein, and a light blocking part disposed to fill the opening. The organic layer is formed between the circuit layer and the pixel-defining film in a thickness direction of the display device.

In an embodiment, the second lower electrode may be directly formed above the organic layer.

In an embodiment, the organic layer may not overlap the first light-emitting layer, and may overlap the second light-emitting layer.

In an embodiment, the organic layer may include an organic material which is a same material as a material of the at least one insulating layer.

In an embodiment, the display device may be a television, a monitor, an outdoor billboard, a tablet computer, a vehicle navigation unit, a personal computer, a laptop computer, a personal digital terminal, a game console, a smart phone, or a camera.

According to an embodiment of the present inventive concept, an electronic device includes a display device. A power supply provides power to the display device. The display device comprises: a circuit layer including a transistor, and at least one insulating layer disposed on the transistor; a display element layer disposed on the circuit layer, the display element layer including a first light-emitting element having a first light-emitting layer, a second light-emitting element having a second light-emitting layer, the second light-emitting element is spaced apart from the first light-emitting element in a first direction perpendicular to a thickness direction of the display device, a pixel-defining film having a first pixel opening and a second pixel opening defined therein, and an organic layer disposed between the circuit layer and the pixel-defining film in the thickness direction of the display device; and a light control layer disposed on the display element layer, the light control layer including a transmission part having an opening defined therein, and a light blocking part disposed to fill the opening and blocking light emitted by the display element layer. The light blocking part overlaps the first light-emitting layer and does not overlap the second light-emitting layer. The first light-emitting element is co-planar with the organic layer. The second light-emitting element is disposed above the organic layer.

In an embodiment, the first light-emitting element is disposed directly above the circuit layer and the second light-emitting element is disposed directly above the organic layer.

### BRIEF DESCRIPTION OF THE DRAWINGS

The accompanying drawings are included to provide a further understanding of embodiments of the present inventive concept, and are incorporated in and constitute a part of this specification. The drawings illustrate non-limiting embodiments of the present inventive concept and, together with the description, serve to explain principles of the present inventive concept. In the drawings:

FIG. 1 is a perspective view illustrating a display device according to an embodiment of the present inventive concept;

FIG. 2 is a cross-sectional view illustrating a portion taken along line I-I′ of FIG. 1 according to an embodiment of the present inventive concept;

FIG. 3 is a plan view illustrating a portion of a display device according to an embodiment of the present inventive concept;

FIG. 4 is a cross-sectional view illustrating a portion taken along line II-II′ of FIG. 3 according to an embodiment of the present inventive concept;

FIG. 5 is an enlarged cross-sectional view illustrating region AA′ of FIG. 4 according to an embodiment of the present inventive concept;

FIG. 6 is a cross-sectional view illustrating a portion of a display device according to an embodiment of the present inventive concept;

FIG. 7 is a view illustrating a vehicle in which a display device according to an embodiment of the present inventive concept is disposed;

FIG. 8 is a flowchart illustrating a manufacturing method for a display device according to an embodiment of the present inventive concept;

FIG. 9 is a view schematically illustrating a display device manufacturing step according to an embodiment of the present inventive concept;

FIG. 10 is a view schematically illustrating a display device manufacturing step according to an embodiment of the present inventive concept;

FIG. 11 is a view schematically illustrating a display device manufacturing step according to an embodiment of the present inventive concept;

FIG. 12 is a view schematically illustrating a display device manufacturing step according to an embodiment of the present inventive concept;

FIG. 13 is a view schematically illustrating a display device manufacturing step according to an embodiment of the present inventive concept;

FIG. 14 is a view schematically illustrating a display device manufacturing step according to an embodiment of the present inventive concept; and

FIG. 15 is a view schematically illustrating a display device manufacturing step according to an embodiment of the present inventive concept.

### DETAILED DESCRIPTION OF EMBODIMENTS

The present inventive concept may be implemented in various modifications and have various forms, and non-limiting embodiments are illustrated in the drawings and described in detail in the text. It is to be understood, however, that embodiments of the present inventive concept are not intended to be limited to the particular forms disclosed, but on the contrary, is intended to cover all modifications, equivalents, and alternatives falling within the spirit and scope of the present inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween. When an element is referred to as being “directly on”, “directly connected to” or “directly coupled to” another element, no intervening elements may be disposed therebetween.

Like reference numerals or symbols refer to like elements throughout. Also, in the drawings, the thickness, the ratio, and the dimension of the elements may be exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of embodiments of the present inventive concept. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

The present inventive concept is directed to a display device that may selectively display images in a first mode in which an exit angle of the image is limited and a second mode in which the exit angle of the image is not limited. The display device may include a first light emitting element that is co-planar with an organic layer and disposed above a circuit layer and a second light emitting element that is disposed above the organic layer and is positioned a farther distance from the circuit layer in the thickness direction of the display device than the first light emitting element. The first and second light emitting elements emit light having a same color as each other. A light control layer includes a light blocking part that overlaps the first light emitting element and does not overlap the second light emitting element.

In a first mode (e.g., a privacy mode), the display device emits images solely with the first light emitting element and the light control layer overlapping the first light emitting element limits the viewing angle of the displayed image. In a second mode (e.g., a general mode), the display device emits images solely with the second light emitting element and the viewing angle of the image is not limited by the light control layer. Since the second light-emitting element is disposed at a relatively higher position in a thickness direction of the display device, degradation of the luminance of the image due to the light blocking part is prevented.

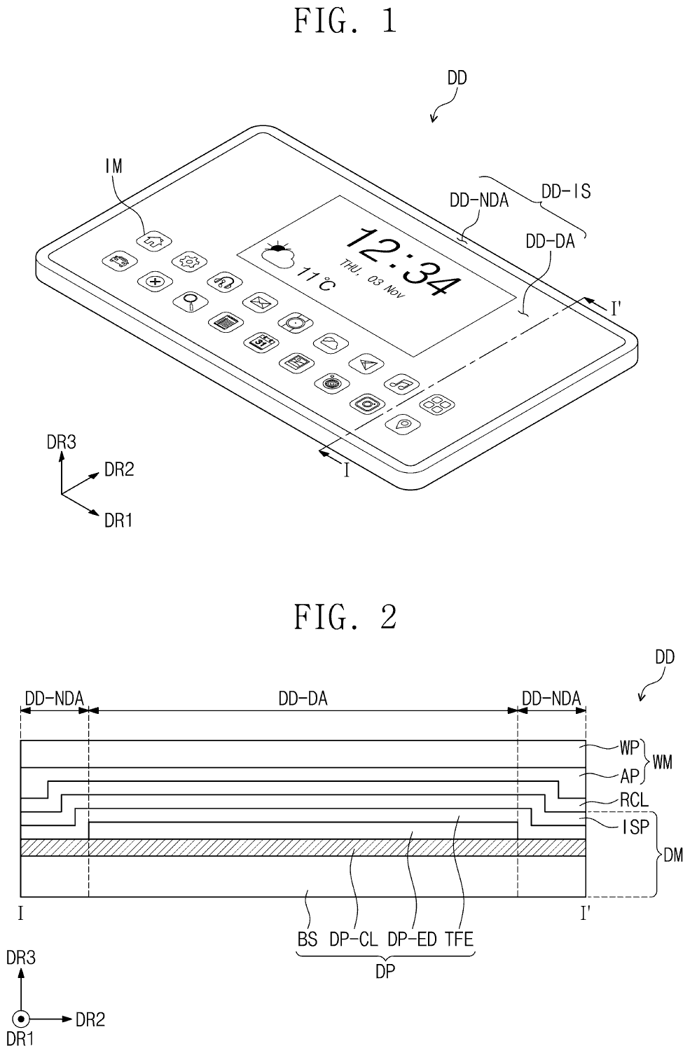

Hereinafter, a display device according to an embodiment of the present inventive concept will be described with reference to the drawings. FIG. 1 is a perspective view illustrating a display device according to an embodiment.

Referring to FIG. 1, a display device DD according to an embodiment may be activated in response to an electrical signal. For example, in an embodiment the display device DD may be applied to an electronic device such as a television, a monitor, an outdoor billboard, a tablet computer, a vehicle navigation unit, a personal computer, a laptop computer, a personal digital terminal, a game console, a smart phone, and a camera. Also, these are merely presented as examples, and the display device DD may also be used as other display devices without departing from the idea of the present inventive concept. For example, the electronic device that the display device DD may be applied to may be various different small-sized, medium-sized or large-sized electronic devices. According to an embodiment of the present disclosure, an electronic device may include the display device DD and a power supply configured to provide power to the display device.

The display device DD may display an image IM through a display surface DD-IS. The image IM may include at least one dynamic image (e.g., a moving image) and/or a static image (e.g., a still image). In an embodiment, the display surface DD-IS may be parallel to a plane defined by a first direction DR1 and a second direction DR2. FIG. 1 illustrates the display device DD provided with a flat display surface DD-IS, but embodiments of the present inventive concept are not necessarily limited thereto. The display device DD may include a curved display surface or a three-dimensional display surface. The three-dimensional display surface may also include a plurality of display regions which respectively indicate different directions.

The display surface DD-IS may include a display region DD-DA and a non-display region DD-NDA. The display device DD may display the image IM through the display region DD-DA of the display surface DD-IS. The non-display region DD-NDA may be adjacent to the display region DD-DA (e.g. in the first and/or second directions DR1, DR2). For example, the non-display region DD-NDA may surround the display region DD-DA (e.g., in a plan view). However, embodiments of the present disclosure are not necessarily limited to the configuration shown in FIG. 1, and the non-display region DD-NDA may be disposed adjacent to only one side of the display region DD-DA or may be omitted in some embodiments.

In FIG. 1 and the following drawings, first to third direction axes DR1, DR2, and DR3 are illustrated, and directions indicated by the first to third direction axes DR1, DR2, and DR3 described herein may have a relative concept and may thus be changed to other directions. In addition, the directions indicated by the first to third direction axes DR1, DR2, and DR3 may be referred to as first to third directions, and may be denoted as the same reference numerals or symbols. In this specification, the first direction axis DR1 and the second direction axis DR2 may be orthogonal to each other, and the third direction axis DR3 may be a normal direction of a plane defined by the first direction axis DR1 and the second direction axis DR2. However, embodiments of the present disclosure are not necessarily limited thereto and the first to third direction axis DR1, DR2, DR3 may cross each other at various different angles.

A thickness direction of the display device DD may be a direction parallel to the third direction axis DR3. An upper side (e.g., a top surface) and a lower side (e.g., a bottom surface) may be defined based on the third direction axis DR3. The upper side (e.g., the top surface) means a direction (or a surface) of getting closer to the display surface DD-IS, and the lower side (or the bottom surface) means a direction (or a surface) of getting farther away from the display surface DD-IS. A cross section means a surface parallel to the thickness direction DR3, and a plane means a surface perpendicular to the thickness direction DR3. For example, a plane means a flat surface defined by the first direction axis DR1 and the second direction axis DR2.

In this specification, the wording “an element overlaps another element” means “overlapping on a plane”. A case where an element overlaps another element is not necessarily limited to a case where the two elements have the same shape or area, but also includes a case where the two elements have different shapes and/or areas from each other and there is only a partial overlap therebetween.

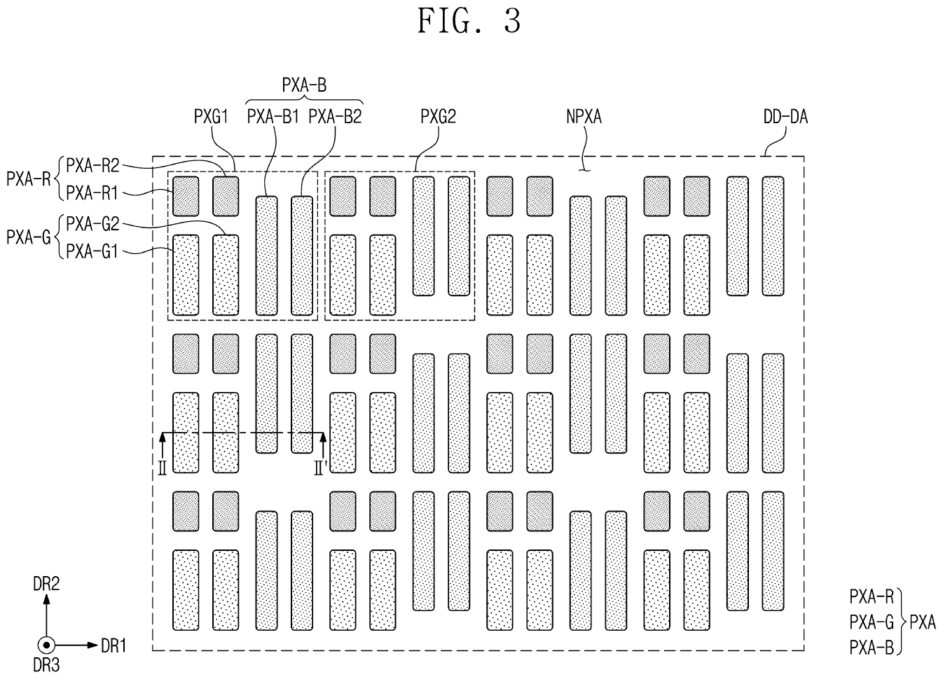

FIG. 2 is a cross-sectional view illustrating a portion taken along line I-I′ of FIG. 1. FIG. 2 may be a cross-sectional view illustrating a display module DM according to an embodiment.

Referring to FIG. 2, in an embodiment the display device DD may include a display module DM, a light control layer RCL disposed on the display module DM, and a window member WM disposed on the light control layer RCL. The display module DM may include a display panel DP and an input-sensing layer ISP disposed on the display panel DP.

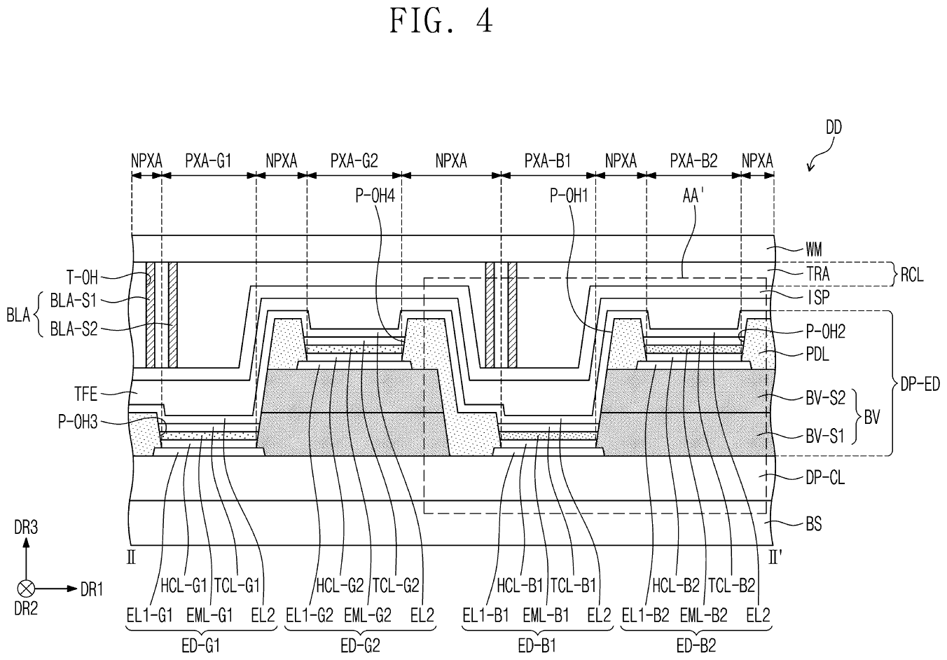

The display panel DP may substantially include at least one capacitor and a plurality of transistors for driving light-emitting elements ED-B1, ED-B2, ED-G1, and ED-G2 (see FIG. 4). The display panel DP may be a component that substantially generates the image IM (see FIG. 1). The display panel DP may be a light-emitting display panel. For example, in an embodiment the display panel DP may be an organic light-emitting display panel, an inorganic light-emitting display panel, a quantum dot display panel, a micro LED display panel, or a nano LED display panel. The display panel DP may be referred to as a display layer. In an embodiment, the display panel DP may include a base layer BS, a circuit layer DP-CL, a display element layer DP-ED, and an encapsulation layer TFE, which are sequentially stacked (e.g., in the third direction DR3).

The base layer BS may be a member which provides a base surface on which the circuit layer DP-CL is disposed. In an embodiment, the base layer BS may be a rigid substrate or a flexible substrate which is bendable, foldable, rollable, etc. In an embodiment, the base layer BS may be a glass substrate, a metal substrate, a polymer substrate, etc. However, embodiments of the present inventive concept are not necessarily limited thereto, and the base layer BS may be an inorganic base layer, an organic base layer, or a composite material layer.

The circuit layer DP-CL may be disposed on the base layer BS (e.g., disposed directly thereon in the third direction DR3). In an embodiment, the circuit layer DP-CL may include an insulating layer, a semiconductor pattern, a conductive pattern, a signal line, etc. In an embodiment, the insulating layer, the semiconductor layer, and the conductive layer are formed on the base layer BS through processes such as coating and deposition, and then the insulating layer, the semiconductor layer, and the conductive layer may be selectively patterned by performing photolithography multiple times. Thereafter, the semiconductor pattern, the conductive pattern, and the signal line included in the circuit layer DP-CL may be formed.

The display element layer DP-ED may be disposed on the circuit layer DP-CL (e.g., disposed directly thereon in the third direction DR3). The display element layer DP-ED may include light-emitting elements ED-B1, ED-B2, ED-G1, and ED-G2 (see FIG. 4). For example, in an embodiment the display element layer DP-ED may include an organic light-emitting material, an inorganic light-emitting material, an organic-inorganic light-emitting material, quantum dots, or quantum rods. The display element layer DP-ED may include a micro LED, or a nano LED.

The encapsulation layer TFE may be disposed on (e.g., disposed directly thereon) the display element layer DP-ED. The encapsulation layer TFE may protect the display element layer DP-ED against moisture, oxygen, and foreign substances such as dust particles.

The input-sensing layer ISP may be disposed on the display panel DP (e.g., disposed directly thereon in the third direction DR3). In an embodiment, the input-sensing layer ISP may detect an external input, change the detected external input to a predetermined input signal, and provide the input signal to the display panel DP. For example, in the display device DD according to an embodiment, the input-sensing layer ISP may be a touch-sensing part which detects a touch. The input-sensing layer ISP may recognize a direct touch by a user, an indirect touch by a user, a direct touch by an object, an indirect touch by an object, etc. However, embodiments of the present disclosure are not necessarily limited thereto and the input-sensing layer ISP may detect various other phenomena in some embodiments.

The input-sensing layer ISP may detect at least one of a position or an intensity (e.g., pressure) of a touch applied from the outside (e.g., the external environment). The display panel DP may receive input signals from the input-sensing layer ISP and generate images corresponding to the input signals. For example, in an embodiment the input-sensing layer ISP may detect an external input in a capacitive manner. However, a driving method for the input-sensing layer ISP is not necessarily limited to any one embodiment.

In an embodiment, the input-sensing layer ISP may be formed on the display panel DP through a continuous process. In this embodiment, the input-sensing layer ISP may be disposed directly on the display panel DP. For example, an additional adhesive member may not be disposed between the input-sensing layer ISP and the display panel DP (e.g., in the third direction DR3). Alternatively, the input-sensing layer ISP may also be bonded to the display panel DP via an adhesive member. The adhesive member may include a typical bonding agent or adhesive agent.

In this specification, when an element is referred to as being directly disposed/formed on another element, there is no intervening element therebetween. For example, the wording, “an element is ‘directly disposed/formed on’ another element” means that an element is ‘in direct contact with’ another element.

The light control layer RCL may limit an exit angle of light emitted from the display panel DP. The light control layer RCL may absorb light propagating at an angle falling out of a certain angle range and limit emission of light to only light propagating at an angle falling within the certain angle range. For example, in an embodiment the light control layer RCL may be a light control film (LCF) applied to a display device for a vehicle. The light control film (LCF) may prevent light, which is emitted from the display device DD, from being reflected at a windshield of a car and obstructing a driver's view. Additionally, the light control layer RCL may be a component provided to protect a user's personal privacy such that an image IM is not visible to other people located around the user of a display device. For example, in an embodiment the light control layer RCL may be directly disposed on the display module DM (e.g., in the third direction DR3).

The window member WM may be disposed on the display module DM (e.g., in the third direction DR3). The window member WM may include a window WP, and an adhesive layer AP. In an embodiment, the window member WM may further include at least one functional layer provided on the window WP. For example, the functional layer may be a hard coating layer, an anti-fingerprint coating layer, etc. However, embodiments of the present inventive concept are not necessarily limited thereto.

The window WP may include an optically transparent insulating material. The window WP may be a glass substrate or a polymer substrate. For example, in an embodiment the window WP may be a tempered glass substrate which has been subjected to reinforcement treatment. Alternatively, the window WP may be formed of polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof. However, embodiments of the present disclosure are not necessarily limited thereto, and a material included in the window WP may vary.

The adhesive layer AP may be disposed between the display module DM and the window WP (e.g., in a third direction DR3). A component adjacent to the window WP such as the display module DM and the light control layer RCL may be bonded to the window WP via the adhesive layer AP. In an embodiment, the adhesive layer AP may include a typical adhesive such as a pressure sensitive adhesive (PSA), an optically clear adhesive (OCA), and an optical clear resin (OCR), but is not necessarily limited to any one embodiment. In some embodiments, the adhesive layer AP may be omitted.

FIG. 3 is an enlarged plan view illustrating a portion of a display region according to an embodiment. Referring to FIG. 3, a display region DD-DA may be divided into a light-emitting region PXA and a peripheral region NPXA. The peripheral region NPXA may surround the light-emitting region PXA (e.g., in a plan view).

The light-emitting region PXA may be provided as a plurality of light-emitting regions which emit light having different wavelength ranges from each other. In an embodiment, the light-emitting region PXA may include a first light-emitting region PXA-B, a second light-emitting region PXA-G, and a third light-emitting region PXA-R. For example, in an embodiment the first light-emitting region PXA-B may emit blue light, the second light-emitting region PXA-G may emit green light, and the third light-emitting region PXA-R may emit red light. However, embodiments of the present inventive concept are not necessarily limited thereto, and the light-emitting regions PXA-B, PXA-G, and PXA-R may emit light having various other colors other than blue light, green light, and red light.

FIG. 3 illustrates that in a plan view, the first light-emitting region PXA-B, the second light-emitting region PXA-G, and the third light-emitting region PXA-R each have a quadrilateral shape having rounded corners. However, embodiments of the present inventive concept are not necessarily limited thereto. For example, the first light-emitting region PXA-B, the second light-emitting region PXA-G, and the third light-emitting region PXA-R may each have a shape such as a polygonal or circular shape (e.g., in a plan view).

In an embodiment, in the light-emitting region PXA, the first light-emitting region PXA-B which emits blue light may have the greatest area (e.g., in a plan view), and the third light-emitting region PXA-R which emits red light may have the smallest area (e.g., in a plan view). Here, the areas may represent areas when viewed on a plane. However, embodiments of the present inventive concept are not necessarily limited thereto and the respective areas of the first light-emitting region PXA-B, the second light-emitting region PXA-G, and the third light-emitting region PXA-R may vary.

In an embodiment, the light-emitting regions PXA-B, PXA-G, and PXA-R may form first and second groups PXG1 and PXG2. On a plane, the first group PXG1 and the second group PXG2 may be alternately disposed along the first direction DR1. On a plane, the first group PXG1 and the second group PXG2 may be alternately disposed along the second direction DR2.

The first and second groups PXG1 and PXG2 may each include the first light-emitting region PXA-B, the second light-emitting region PXA-G, and the third light-emitting region PXA-R. In the first direction DR1, the edge of the first light-emitting region PXA-B of the first group PXG1 may not be parallel to the edge of the first light-emitting region PXA-B of the second group PXG2. In an embodiment, in the first group PXG1, the edge of the first light-emitting region PXA-B may be parallel to the edge of the second light-emitting region PXA-G. In this embodiment, the edge of the first light-emitting region PXA-B and the edge of the second light-emitting region PXA-G may be parallel to the first direction DR1. In an embodiment, in the second group PXG2, the edge of the first light-emitting region PXA-B may be parallel to the edge of the third light-emitting region PXA-R. In this embodiment, the edge of the first light-emitting region PXA-B and the edge of the third light-emitting region PXA-R may be parallel to the first direction DR1.

In each of the first and second groups PXG1 and PXG2, the first light-emitting region PXA-B may include a first blue-light-emitting region PXA-B1 and a second blue-light-emitting region PXA-B2. In each of the first and second groups PXG1 and PXG2, the first blue-light-emitting region PXA-B1 and the second blue-light-emitting region PXA-B2 may be spaced apart from each other along the first direction DR1. On a plane, the area of the first blue-light-emitting region PXA-B1 may be substantially the same as the area of the second blue-light-emitting region PXA-B2. In this specification, the wording “substantially the same” includes a case where physical values are same and a case where a difference falls within a process tolerance range.

In each of the first and second groups PXG1 and PXG2, the second light-emitting region PXA-G may include a first green-light-emitting region PXA-G1 and a second green-light-emitting region PXA-G2. In each of the first and second groups PXG1 and PXG2, the first green-light-emitting region PXA-G1 and the second green-light-emitting region PXA-G2 may be spaced apart from each other along the first direction DR1. On a plane, the area of the first green-light-emitting region PXA-G1 may substantially be the same as the area of the second green-light-emitting region PXA-G2.

In each of the first and second groups PXG1 and PXG2, the third light-emitting region PXA-R may include a first red-light-emitting region PXA-R1 and a second red-light-emitting region PXA-R2. In each of the first and second groups PXG1 and PXG2, the first red-light-emitting region PXA-R1 and the second red-light-emitting region PXA-R2 may be spaced apart from each other along the first direction DR1. On a plane, the area of the first red-light-emitting region PXA-R1 may substantially be the same as the area of the second red-light-emitting region PXA-R2.

The peripheral regions NPXA may be regions which are between the adjacent light-emitting regions PXA-B, PXA-G, and PXA-R and correspond to pixel-defining films PDL to be described later (see FIG. 4). The light-emitting regions PXA-B, PXA-G, and PXA-R may each correspond to a pixel.

FIG. 4 is a cross-sectional view illustrating a portion taken along line II-II′ of FIG. 3. FIG. 4 may be a cross-sectional view illustrating a display device DD according to an embodiment.

A base layer BS may have a single-layered or a multi-layered structure. For example, in an embodiment the base layer BS may include a first synthetic resin layer, an intermediate layer having a multi-layered or single-layered structure, and a second synthetic resin layer, which are sequentially stacked (e.g., in the third direction DR3). The intermediate layer may be referred to as a base barrier layer. In an embodiment, the intermediate layer may include a silicon oxide (SiOₓ) layer and an amorphous silicon (a-Si) layer disposed on the silicon oxide layer. However, embodiments of the present inventive concept are not necessarily limited thereto. For example, the intermediate layer may include at least one of a silicon oxide layer, a silicon nitride layer, a silicon oxynitride layer, or an amorphous silicon layer.

The first and second synthetic resin layers may each include a polyimide-based resin. Also, the first and second synthetic resin layers may each include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜ based” resin is considered as including a functional group of “˜˜”.

In an embodiment, a circuit layer DP-CL may include an insulating layer, a semiconductor pattern, a conductive pattern, a signal line, etc. For example, the circuit layer DP-CL may include a driving transistor and a switching transistor for driving light-emitting elements ED-G1, ED-G2, ED-B1, and ED-B2 of a display element layer DP-ED.

In an embodiment, the display element layer DP-ED may include the light-emitting elements ED-B1, ED-B2, ED-G1, and ED-G2, pixel-defining films PDL, and organic layers BV. The pixel-defining films PDL may separate the light-emitting elements ED-B1, ED-B2, and ED-G1, ED-G2 from each other. For example, light-emitting layers EML-B1, EML-B2, EML-G1, and EML-G2 of the light-emitting elements ED-B1, ED-B2, ED-G1, and ED-G2 may be respectively disposed in pixel openings P-OH1, P-OH2, P-OH3, and P-OH4 defined in the pixel-defining films PDL, and may be separated from each other.

In an embodiment, first to fourth pixel openings P-OH1, P-OH2, P-OH3, and P-OH4 may be defined in the pixel-defining films PDL. The first to fourth pixel openings P-OH1, P-OH2, P-OH3, and P-OH4 may be spaced apart from each other in the first direction DR1 perpendicular to the thickness direction DR3. For example, the pixel-defining films PDL may include an organic light blocking material or an inorganic light blocking material. The organic light blocking material or the inorganic light blocking material may each include a black pigment and/or a black dye.

In an embodiment, the display element layer DP-ED may include first to fourth light-emitting elements ED-B1, ED-B2, ED-G1, and ED-G2. The first to fourth light-emitting elements ED-B1, ED-B2, ED-G1, and ED-G2 may be spaced apart from each other in the first direction DR1 perpendicular to the thickness direction DR3. The first to fourth light-emitting elements ED-B1, ED-B2, ED-G1, and ED-G2 may respectively include lower electrodes EL1-B1, EL1-B2, EL1-G1, and EL1-G2, an upper electrode EL2, and the light-emitting layers EML-B1, EML-B2, EML-G1, and EML-G2. The upper electrode EL2 may be disposed on the lower electrodes EL1-B1, EL1-B2, EL1-G1, and EL1-G2. The light-emitting layers EML-B1, EML-B2, EML-G1, and EML-G2 may be disposed between the lower electrodes EL1-B1, EL1-B2, EL1-G1, and EL1-G2 and the upper electrode EL2 (e.g., in the third direction DR3). Additionally, the first to fourth light-emitting elements ED-B1, ED-B2, ED-G1, and ED-G2 may respectively further include hole control layers HCL-B1, HCL-B2, HCL-G1, and HCL-G2, and electron control layers TCL-B1, TCL-B2, TCL-G1, and TCL-G2. The hole control layers HCL-B1, HCL-B2, HCL-G1, and HCL-G2 may be disposed between the lower electrodes EL1-B1, EL1-B2, EL1-G1, and EL1-G2 and the light-emitting layers EML-B1, EML-B2, EML-G1, and EML-G2 (e.g., in the third direction DR3). The electron control layers TCL-B1, TCL-B2, TCL-G1, and TCL-G2 may be disposed between the light-emitting layers EML-B1, EML-B2, EML-G1, and EML-G2 and the upper electrode EL2 (e.g., in the third direction DR3).

The first light-emitting element ED-B1 may include a first lower electrode EL1-B1, a first upper electrode EL2 disposed on the first lower electrode EL1-B1, and a first light-emitting layer EML-B1 disposed between the first lower electrode EL1-B1 and the first upper electrode EL2 (e.g., in the third direction DR3). The first lower electrode EL1-B1 may be exposed in the first pixel opening P-OH1. The first light-emitting element ED-B1 may further include a first hole control layer HCL-B1 disposed between the first lower electrode EL1-B1 and the first light-emitting layer EML-B1 (e.g., in the third direction DR3), and a first electron control layer TCL-B1 disposed between the first light-emitting layer EML-B1 and the first upper electrode EL2 (e.g., in the third direction DR3).

The second light-emitting element ED-B2 may include a second lower electrode EL1-B2, a second upper electrode EL2 disposed on the second lower electrode EL1-B2, and a second light-emitting layer EML-B2 disposed between the second lower electrode EL1-B2 and the second upper electrode EL2 (e.g., in the third direction DR3). The second lower electrode EL1-B2 may be exposed in the second pixel opening P-OH2. The second light-emitting element ED-B2 may further include a second hole control layer HCL-B2 disposed between the second lower electrode EL1-B2 and the second light-emitting layer EML-B2 (e.g., in the third direction DR3), and a second electron control layer TCL-B2 disposed between the second light-emitting layer EML-B2 and the second upper electrode EL2 (e.g., in the third direction DR3).

The third light-emitting element ED-G1 may include a third lower electrode EL1-G1, a third upper electrode EL2 disposed on the third lower electrode EL1-G1, and a third light-emitting layer EML-G1 disposed between the third lower electrode EL1-G1 and the third upper electrode EL2 (e.g., in the third direction DR3). The third lower electrode EL1-G1 may be exposed in the third pixel opening P-OH3. The third light-emitting element ED-G1 may further include a third hole control layer HCL-G1 disposed between the third lower electrode EL1-G1 and the third light-emitting layer EML-G1 (e.g., in the third direction DR3), and a third electron control layer TCL-G1 disposed between the third light-emitting layer EML-G1 and the third upper electrode EL2 (e.g., in the third direction DR3).

The fourth light-emitting element ED-G2 may include a fourth lower electrode EL1-G2, a fourth upper electrode EL2 disposed on the fourth lower electrode EL1-G2, and a fourth light-emitting layer EML-G2 disposed between the fourth lower electrode EL1-G2 and the fourth upper electrode EL2 (e.g., in the third direction DR3). The fourth lower electrode EL1-G2 may be exposed in the fourth pixel opening P-OH4. The fourth light-emitting element ED-G2 may further include a fourth hole control layer HCL-G2 disposed between the fourth lower electrode EL1-G2 and the fourth light-emitting layer EML-G2 (e.g., in the third direction DR3), and a fourth electron control layer TCL-G2 disposed between the fourth light-emitting layer EML-G2 and the fourth upper electrode EL2 (e.g., in the third direction DR3).

At least one among the first to fourth light-emitting elements ED-B1, ED-B2, ED-G1, and ED-G2 may emit light having a wavelength range different from the others. In an embodiment, the first to fourth light-emitting elements ED-B1, ED-B2, ED-G1, and ED-G2 may each emit light having at least one color of red, green, and blue. The red light may be light having a wavelength range of about 630 nm to about 750 nm. The green light may be light having a wavelength range of about 495 nm to about 570 nm. The blue light may be light having a wavelength range of about 430 nm to about 490 nm.

The first light-emitting element ED-B1 and the third light-emitting element ED-G1 may emit light having wavelength ranges different from each other. The first light-emitting element ED-B1 and the second light-emitting element ED-B2 may emit light having the same wavelength range as each other. The first light-emitting element ED-B1 and the second light-emitting element ED-B2 may emit light having substantially the same color as each other. The third light-emitting element ED-G1 and the fourth light-emitting element ED-G2 may emit light having the same wavelength ranges as each other. The third light-emitting element ED-G1 and the fourth light-emitting element ED-G2 may emit light having substantially the same color as each other.

The first light-emitting element ED-B1 and the second light-emitting element ED-B2 may each emit light having a first wavelength range. The third light-emitting element ED-G1 and the fourth light-emitting element ED-G2 may each emit light having a second wavelength range different from the first wavelength range. For example, in an embodiment the first light-emitting element ED-B1 and the second light-emitting element ED-B2 may each emit light having a blue wavelength range. The third light-emitting element ED-G1 and the fourth light-emitting element ED-G2 may each emit light having a green wavelength range.

The first light-emitting layer EML-B1 of the first light-emitting element ED-B1 may correspond to the first blue-light-emitting region PXA-B1. The second light-emitting layer EML-B2 of the second light-emitting element ED-B2 may correspond to the second blue-light-emitting region PXA-B2. The third light-emitting layer EML-G1 of the third light-emitting element ED-G1 may correspond to the first green-light-emitting region PXA-G1. The fourth light-emitting layer EML-G2 of the fourth light-emitting element ED-G2 may correspond to the second green-light-emitting region PXA-G2. However, embodiments of the present inventive concept are not necessarily limited thereto, and the first to fourth light-emitting elements ED-B1, ED-B2, ED-G1, and ED-G2 may also emit light having the same color as each other in some embodiments. For example, in an embodiment each of the first to fourth light-emitting elements ED-B1, ED-B2, ED-G1, and ED-G2 may emit a same blue light or white light.

The first to fourth lower electrodes EL1-B1, EL1-B2, EL1-G1, and EL1-G2 may each be formed of a metal material, a metal alloy, or a conductive compound. The first to fourth lower electrodes EL1-B1, EL1-B2, EL1-G1, and EL1-G2 may each be an anode or a cathode. The first to fourth lower electrodes EL1-B1, EL1-B2, EL1-G1, and EL1-G2 may each be a pixel electrode. The first to fourth lower electrodes EL1-B1, EL1-B2, EL1-G1, and EL1-G2 may be a transmissive electrode, a transflective electrode, or a reflective electrode.

In an embodiment, the first to fourth lower electrodes EL1-B1, EL1-B2, EL1-G1, and EL1-G2 may each include: at least one compound selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from thereamong; a mixture of two or more materials selected from thereamong; or oxides thereof.

In an embodiment in which the first to fourth lower electrodes EL1-B1, EL1-B2, EL1-G1, and EL1-G2 are each the transmissive electrode, the first to fourth lower electrodes EL1-B1, EL1-B2, EL1-G1, and EL1-G2 may each include a transparent metal oxide, for example, indium tin oxide (ITO), indium zinc oxide (IZO), zinc oxide (ZnO), indium tin zinc oxide (ITZO), etc.

In an embodiment in which the first to fourth lower electrodes EL1-B1, EL1-B2, EL1-G1, and EL1-G2 are each the transflective electrode or the reflective electrode, the first to fourth lower electrodes EL1-B1, EL1-B2, EL1-G1, and EL1-G2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). Alternatively, the first to fourth lower electrodes EL1-B1, EL1-B2, EL1-G1, and EL1-G2 may each have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the first to fourth lower electrodes EL1-B1, EL1-B2, EL1-G1, and EL1-G2 may each have a three-layered structure of ITO/Ag/ITO. However, embodiments of the present disclosure are not necessarily limited thereto. Additionally, in some embodiments the first to fourth lower electrodes EL1-B1, EL1-B2, EL1-G1, and EL1-G2 may each include the above-described metal materials, a combination of two or more metal materials selected from thereamong, oxides of the above-described metal materials, etc.

The first to fourth hole control layers HCL-B1, HCL-B2, HCL-G1, and HCL-G2 may have a single layer formed of a single material, a single layer formed of a plurality of materials different from each other, or a multi-layered structure which has a plurality of layers formed of a plurality of materials different from each other. The first to fourth hole control layers HCL-B1, HCL-B2, HCL-G1, and HCL-G2 may each include a typical hole injection material and/or a typical hole transport material. The first to fourth hole control layers HCL-B1, HCL-B2, HCL-G1, and HCL-G2 may include at least one of a hole injection layer, a hole transport layer, or an electron blocking layer. The first to fourth hole control layers HCL-B1, HCL-B2, HCL-G1, and HCL-G2 may respectively overlap corresponding regions among the blue and green light-emitting regions PXA-B1, PXA-B2, PXA-G1, and PXA-G2. In some embodiments, the first to fourth hole control layers HCL-B1, HCL-B2, HCL-G1, and HCL-G2 may be provided as a common layer so as to overlap the blue and green light-emitting regions PXA-B1, PXA-B2, PXA-G1, and PXA-G2, and a peripheral region NPXA.

The first to fourth light-emitting layers EML-B1, EML-B2, EML-G1, and EML-G2 may each include an organic light-emitting material or an inorganic light-emitting material. For example, in an embodiment the first to fourth light-emitting layers EML-B1, EML-B2, EML-G1, and EML-G2 may each include a fluorescent or phosphorescent material. The first to fourth light-emitting layers EML-B1, EML-B2, EML-G1, and EML-G2 may each include quantum dots as a light-emitting material.

The first to fourth electron control layers TCL-B1, TCL-B2, TCL-G1, and TCL-G2 may each have a single layer formed of a single material, a single layer formed of a plurality of materials different from each other, or a multi-layered structure which has a plurality of layers formed of a plurality of materials different from each other. The first to fourth electron control layers TCL-B1, TCL-B2, TCL-G1, and TCL-G2 may each include a typical electron injection material and/or a typical electron transport material. In an embodiment, the first to fourth electron control layers TCL-B1, TCL-B2, TCL-G1, and TCL-G2 may each include at least one among an electron injection layer, an electron transport layer, and a hole blocking layer. The first to fourth electron control layers TCL-B1, TCL-B2, TCL-G1, and TCL-G2 may respectively overlap corresponding regions among the blue and green light-emitting regions PXA-B1, PXA-B2, PXA-G1, and PXA-G2. In some embodiments, the first to fourth electron control layers TCL-B1, TCL-B2, TCL-G1, and TCL-G2 may be provided as a common layer so as to overlap the blue and green light-emitting regions PXA-B1, PXA-B2, PXA-G1, and PXA-G2, and the peripheral region NPXA.

The first to fourth upper electrodes EL2 may be a common electrode. Accordingly, the same reference numerals or symbols are given to the first to fourth upper electrodes EL2. Hereinafter, the description of the upper electrode EL2 may be similarly applied to the first to fourth upper electrodes EL2.

The upper electrode EL2 may be a cathode or an anode. However, embodiments of the present inventive concept are not necessarily limited thereto. For example, in an embodiment in which the first to fourth lower electrodes EL1-B1, EL1-B2, EL1-G1, and EL1-G2 are anodes, the upper electrode EL2 may be a cathode, and in an embodiment in which the first to fourth lower electrodes EL1-B1, EL1-B2, EL1-G1, and EL1-G2 are cathodes, the upper electrode EL2 may be an anode. The upper electrode EL2 may be a transmissive electrode, a transflective electrode, or a reflective electrode. In an embodiment in which the upper electrode EL2 is the transmissive electrode, the upper electrode EL2 may be formed of a transparent metal oxide, for example, indium tin oxide (ITO), indium zinc oxide (IZO), zinc oxide (ZnO), indium tin zinc oxide (ITZO), etc.

In an embodiment in which the upper electrode EL2 is the transflective electrode or the reflective electrode, the upper electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or a mixture thereof (for example, AgMg, AgYb, or MgYb). Alternatively, the upper electrode EL2 may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the upper electrode EL2 may include the above-described metal materials, a combination of two or more metal materials selected from thereamong, oxides of the above-described metal materials, or the like.

In an embodiment, a capping layer may be disposed on the first to fourth light-emitting elements ED-B1, ED-B2, ED-G1, and ED-G2 (e.g., in the third direction DR3). The capping layer may be an organic capping layer, or an inorganic capping layer. For example, in an embodiment in which the capping layer includes an inorganic material, the inorganic material may include an alkali metal compound such as LiF, an alkali earth-metal compound such as MgF₂, SiON, SiNₓ, SiO_{y}, etc. For example, in an embodiment in which the capping layer includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-Tris(carbazol-9-yl)triphenylamine) (TCTA), etc., or may include an epoxy resin or acrylate such as methacrylate.

The organic layer BV may be disposed between the circuit layer DP-CL and the pixel-defining film PDL (e.g., in the third direction DR3). Some portions of the first to fourth light-emitting elements ED-B1, ED-B2, ED-G1, and ED-G2 may be disposed on the same layer as the organic layer BV (e.g., be co-planar therewith), and the other portions may be disposed on the organic layer BV, such as above the organic layer BV in the third direction DR3. One among the first and second light-emitting elements ED-B1 and ED-B2 which emit light having the same color may be disposed on the same layer as the organic layer BV, and the other may be disposed on the organic layer BV, such as disposed above the organic layer BV (e.g., in the third direction DR3). In an embodiment, the first light-emitting element ED-B1 may be disposed on the same layer as the organic layer BV, and the second light-emitting element ED-B2 may be disposed on the organic layer BV, such as disposed above (e.g., directly thereabove) the organic layer BV in the third direction DR3. The first light-emitting element ED-B1 and the organic layer BV may be disposed on the circuit layer DP-CL (e.g., disposed directly thereon in the third direction DR3), and the second light-emitting element ED-B2 may be disposed on the organic layer BV (e.g., directly thereabove in the third direction DR3). The first lower electrode EL1-B1 of the first light-emitting element ED-B1 may be spaced apart from the second lower electrode EL1-B2 of the second light-emitting element ED-B2 with the organic layer BV therebetween in the first direction DR1 perpendicular to the thickness direction DR3. The first lower electrode EL1-B1 of the first light-emitting element ED-B1 may be directly disposed on the same layer as the organic layer BV, and the second lower electrode EL1-B2 of the second light-emitting element ED-B2 may be directly disposed on (e.g., disposed above) the organic layer BV. The first lower electrode EL1-B1 of the first light-emitting element ED-B1, and the organic layer BV may be directly disposed on the circuit layer DP-CL (e.g., in the third direction DR3). Accordingly, the second light-emitting element ED-B2 may be disposed at a relatively higher position than the first light-emitting element ED-B1 in the thickness direction DR3. The second light-emitting element ED-B2 may be disposed closer to the display surface DD-IS (see FIG. 1) than the first light-emitting element ED-B1.

In an embodiment, a light-emitting mode of the display device DD may be divided into a first mode and a second mode. The first mode may be a privacy mode in which an exit angle is limited. In contrast, the second mode may be a general mode in which an exit angle is not limited. For example, in a display device for a vehicle, the first mode may serve as a mode in which an image is not visible to a driver for safety but visible only to a passenger (e.g., a front-seat passenger). In the first mode, light emission may be limited in a lateral direction. The second mode may be a mode in which an image is visible to both a driver and a passenger.

In the display device DD according to an embodiment, the light-emitting element which emits light in the first mode may be different from the light-emitting element which emits light in the second mode. One of two light-emitting elements which emit light having the same color as each other may emit light in the first mode, and may not emit light in the second mode. The other of the two light-emitting elements which emit light having the same color as each other may not emit light in the first mode, and may emit light in the second mode. In an embodiment, the first light-emitting element ED-B1 among the first and second light-emitting elements ED-B1 and ED-B2 which emit light having the same color may emit light in the first mode, and may not emit light in the second mode. For example, in an embodiment the second light-emitting element ED-B2 may not emit light in the first mode, and may emit light in the second mode.

In an embodiment, to limit an exit angle of light in the first mode, the display device DD may include a light control layer RCL including a light blocking part BLA to be described later. However, the light blocking part BLA may partially limit an exit angle of light even in the second mode, which results in luminance degradation. In contrast, since the display device DD according to an embodiment includes the organic layer BV disposed between the circuit layer DP-CL and the pixel-defining film PDL, and the second light-emitting element ED-B2 disposed on the organic layer BV, it is possible to minimize (or prevent) luminance degradation in the second mode. The second light-emitting element ED-B2 disposed on the organic layer BV is disposed at a relatively higher position in the thickness direction DR3, thereby making it possible to minimize (or prevent) an effect of the light blocking part BLA on the light emitted from the second light-emitting element ED-B2. Accordingly, the display device DD according to an embodiment may exhibit excellent display quality.

One among the third and fourth light-emitting elements ED-G1 and ED-G2 which emit light having the same color may be disposed on the same layer as the organic layer BV, and the other may be disposed on the organic layer BV, such as above the organic layer BV (e.g., in the third direction DR3). In an embodiment, the third light-emitting element ED-G1 may be disposed on the same layer as the organic layer BV, and the fourth light-emitting element ED-G2 may be disposed on the organic layer BV, such as above the organic layer BV (e.g., in the third direction DR3). The third lower electrode EL1-G1 of the third light-emitting element ED-G1 may be spaced apart from the fourth lower electrode EL1-G2 of the fourth light-emitting element ED-G2 with the organic layer BV therebetween in the first direction DR1 perpendicular to the thickness direction DR3. The third lower electrode EL1-G1 of the third light-emitting element ED-G1 may be directly disposed on the same layer as the organic layer BV, and the fourth lower electrode EL1-G2 of the fourth light-emitting element ED-G2 may be directly disposed on the organic layer BV, such as directly above the organic layer BV (e.g., in the third direction DR3). The third lower electrode EL1-G1 of the third light-emitting element ED-G1, and the organic layer BV may be directly disposed on the circuit layer DP-CL. Accordingly, the fourth light-emitting element ED-G2 may be disposed at a relatively higher position than the third light-emitting element ED-G1 in the thickness direction DR3. The fourth light-emitting element ED-G2 may be disposed closer to the display surface DD-IS (see FIG. 1) than the third light-emitting element ED-G1.

In an embodiment, the third light-emitting element ED-G1 among the third and fourth light-emitting elements ED-G1 and ED-G2 which emit light having the same color as each other may emit light in the first mode, and may not emit light in the second mode. The fourth light-emitting element ED-G2 may not emit light in the first mode, and may emit light in the second mode. The display device DD according to an embodiment includes the organic layer BV disposed between the circuit layer DP-CL and the pixel-defining film PDL, and the fourth light-emitting element ED-G2 disposed on the organic layer BV, and thus it is possible to minimize (or prevent) luminance degradation in the second mode. The fourth light-emitting element ED-G2 disposed on the organic layer BV is disposed at a relatively higher position in the thickness direction DR3, thereby making it possible to minimize (or prevent) an effect of the light blocking part BLA on the light emitted from the fourth light-emitting element ED-G2. Accordingly, the display device DD according to an embodiment may exhibit excellent display quality.

In an embodiment, the organic layer BV may include a plurality of sub-organic layers BV-S1 and BV-S2 stacked in the thickness direction DR3. For example, in an embodiment the organic layer BV may include a first sub-organic layer BV-S1 and a second sub-organic layer BV-S2 disposed on (e.g., disposed directly thereabove) the first sub-organic layer BV-S1. In an embodiment, the first sub-organic layer BV-S1 and the second sub-organic layer BV-S2 may include the same organic material as each other. In this embodiment, the first sub-organic layer BV-S1 and the second sub-organic layer BV-S2 may not be seen as separate two layers, but may be seen as a single layer. In some embodiments, the organic layer BV may also include three or more sub-organic layers.

An encapsulation layer TFE may be disposed on the display element layer DP-ED (e.g., disposed directly thereon in the third direction DR3). The encapsulation layer TFE may include at least one inorganic film (hereinafter, referred to as an encapsulation inorganic film). Additionally, the encapsulation layer TFE may include at least one organic film (hereinafter, referred to as an encapsulation organic film) and at least one encapsulation inorganic film.

The encapsulation inorganic film may protect the display element layer DP-ED against moisture/oxygen, and the encapsulation organic film may protect the display element layer DP-ED against foreign substances such as dust particles. In an embodiment, the encapsulation inorganic film may include silicon nitride, silicon oxynitride, silicon oxide, titanium oxide, or aluminum oxide, etc., but is not necessarily limited thereto. The encapsulation organic film may include an acryl-based compound, an epoxy-based compound, etc. The encapsulation organic film may include a photopolymerizable organic material, but is not particularly limited.

An input-sensing layer ISP may be disposed on the encapsulation layer TFE (e.g., disposed directly thereon in the third direction DR3). The light control layer RCL may be disposed on the input-sensing layer ISP (e.g., in the third direction DR3). In an embodiment, the light control layer RCL may be formed on the input-sensing layer ISP through a continuous process. In this embodiment, the light control layer RCL may be disposed directly on the input-sensing layer ISP.

In an embodiment, the light control layer RCL may include a light blocking part BLA and a transmission part TRA. An opening T-OH may be defined in the transmission part TRA. The light blocking part BLA may be disposed to fill the opening T-OH of the transmission part TRA.

An upper surface of the transmission part TRA may be flat. The transmission part TRA may include an optically transparent organic material. For example, in an embodiment the transmission part TRA may include at least one of a polyimide-based resin, an acryl-based resin, or a siloxane-based resin. However, this is presented as an example, and a material from which the transmission part TRA is formed is not necessarily limited thereto.

The transmission part TRA may be formed by adopting any light absorbing material known in the art without limitation. For example, in an embodiment a dark-colored pigment such as a black pigment or a gray pigment, a dark-colored dye, a metal such as aluminum or silver, a metal oxide, a dark-colored polymer, etc., may be used as the light absorbing material.

The light blocking part BLA may overlap a light-emitting element disposed on the same layer as the organic layer BV, and may not overlap a light-emitting element disposed on the organic layer BV. The light blocking part BLA may overlap light-emitting elements (for example, the first light-emitting element ED-B1 and the third light-emitting element ED-G1) which emit light in the first mode, and may not overlap light-emitting elements (for example, the second light-emitting element ED-B2 and the fourth light-emitting element ED-G2) which emit light in the second mode). The light blocking part BLA may not overlap the organic layer BV. In an embodiment, the light blocking part BLA may overlap the first light-emitting layer EML-B1, and may not overlap the second light-emitting layer EML-B2. In an embodiment, the light blocking part BLA may overlap the first lower electrode EL1-B1 and may not overlap the second lower electrode EL1-B2. In an embodiment, the light blocking part BLA may overlap the third light-emitting layer EML-G1, and may not overlap the fourth light-emitting layer EML-G2. In an embodiment, the light blocking part BLA may overlap the third lower electrode EL1-G1 and may not overlap the fourth lower electrode EL1-G2.

The light blocking part BLA may include a plurality of sub-light blocking parts spaced apart from each other in the first direction DR1 perpendicular to the thickness direction DR3. In an embodiment, the light blocking part BLA may include a first sub-light blocking part BLA-S1 and a second sub-light blocking part BLA-S2. The first sub-light blocking part BLA-S1 and the second sub-light blocking part BLA-S2 may be spaced apart from each other in the first direction DR1 perpendicular to the thickness direction DR3. In an embodiment, the first sub-light blocking part BLA-S1 may be disposed in the peripheral region NPXA. The first sub-light blocking part BLA-S1 may overlap the pixel-defining film PDL. The second sub-light blocking part BLA-S2 may be disposed in the first blue-light-emitting region PXA-B1, and the first green-light-emitting region PXA-G1. The second sub-light blocking part BLA-S2 may overlap the first light-emitting layer EML-B1. The second sub-light blocking part BLA-S2 may overlap the third light-emitting layer EML-G1. Neither of the first sub-light blocking part BLA-S1 and the second sub-light blocking part BLA-S2 may overlap the second light-emitting layer EML-B2 and the fourth light-emitting layer EML-G2.

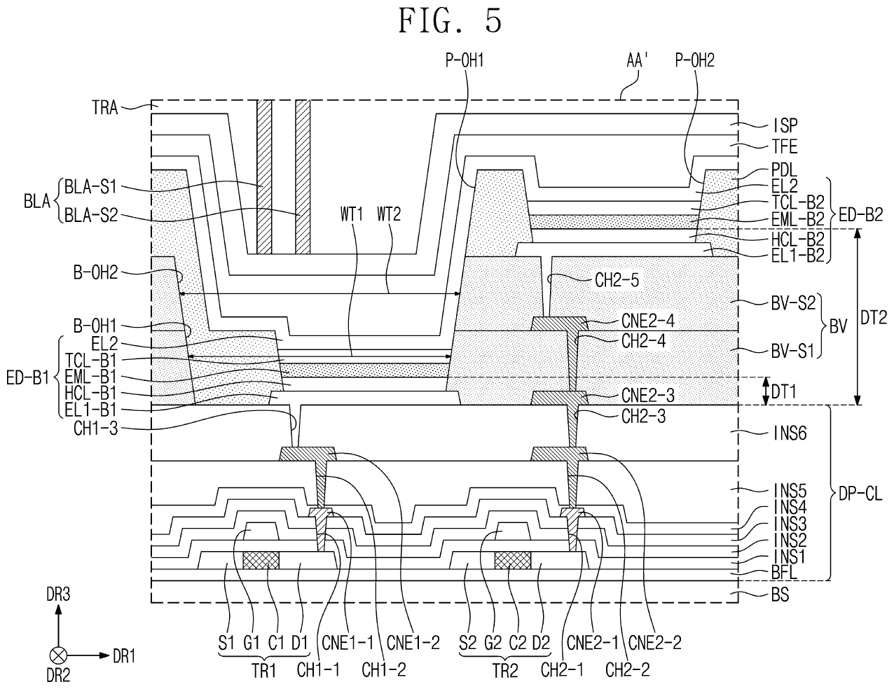

FIG. 5 is an enlarged cross-sectional view illustrating region AA′ of FIG. 4. Hereinafter, with regard to the descriptions of FIG. 5, the contents duplicated with those described with the references to FIGS. 1 to 4 may not be explained again for economy of explanation, and the following description will be mainly focused on the differences therebetween.

Referring to FIG. 5, in an embodiment a circuit layer DP-CL may include first and second transistors TR1 and TR2, a plurality of insulating layers BFL, and INS1 to INS6 disposed on the transistors TR1 and TR2, and connection electrodes CNE1-1, CNE1-2, CNE2-1, and CNE2-2. In an embodiment, the plurality of insulating layers BFL, and INS1 to INS6 may include a buffer layer BFL, and first to sixth insulating layers INS1 to INS6. However, embodiments of the present disclosure are not necessarily limited thereto and the number of the insulating layers may vary. The connection electrodes CNE1-1, CNE1-2, CNE2-1, and CNE2-2 may electrically connect the transistors TR1 and TR2 and the light-emitting elements ED-B1 and ED-B2. However, the configuration of the circuit layer DP-CL illustrated in FIG. 5 is exemplarily illustrated, and the number of transistors, the positions of transistors, the number of insulating layers, the number of connection electrodes, positions of connection electrodes, etc., are not necessarily limited to what an embodiment shown in FIG. 5.

The buffer layer BFL may be disposed on the base layer BS (e.g., disposed directly thereon in the third direction DR3). The buffer layer BFL may include an inorganic layer. The buffer layer BFL may increase a bonding force between the base layer BS and a semiconductor pattern or a conductive pattern which is disposed on the buffer layer BFL.

The first and second transistors TR1 and TR2 may be disposed on the buffer layer BFL (e.g., disposed directly thereon in the third direction DR3). FIG. 5 illustrates that the first transistor TR1 and the second transistor TR2 are disposed on the same layer as each other. However, embodiments of the present disclosure are not necessarily limited thereto and the first transistor TR1 and the second transistor TR2 may be disposed on different layers from each other.

The first transistor TR1 may include a first source S1, a first channel C1, a first drain D1, and a first gate G1. The second transistor TR2 may include a second source S2, a second channel C2, a second drain D2, and a second gate G2. The sources S1 and S2, the channels C1 and C2, and the drains D1 and D2 of the respective first and second transistors TR1 and TR2 may each be formed from semiconductor patterns. In an embodiment, the semiconductor patterns of the transistors TR1 and TR2 may include polysilicon, amorphous silicon, or a metal oxide. However, any material may be used without limitation as long as having semiconductor properties, but is not necessarily limited to any one embodiment.

The semiconductor patterns may include a plurality of regions divided according to conductivity levels. In the semiconductor patterns, a region, which is doped with a dopant or in which a metal oxide is reduced, may have a high conductivity, and may serve substantially as a source electrode and a drain electrode of each of the transistors TR1 and TR2. Highly conductive regions of the semiconductor patterns may correspond to the sources S1 and S2 and the drains D1 and D2 of the respective transistors TR1 and TR2. In the semiconductor patterns, a low conductive region, which is undoped or lightly doped or in which a metal oxide is not reduced, may correspond to the channels C1 and C2 (e.g., an active) of the transistors TR1 and TR2.

The first insulating layer INS1 may cover the semiconductor patterns of the transistors TR1 and TR2 and be disposed on the buffer layer BFL (e.g., disposed directly thereon in the third direction DR3). The first and second gates G1 and G2 of the first and second transistors TR1 and TR2 may be disposed on the first insulating layer INS1 (e.g., disposed directly thereon in the third direction DR3). On a plane, the first gate G1 may overlap the first channel C1 of the first transistor TR1. On a plane, the second gate G2 may overlap the second channel C2 of the second transistor TR2. In an embodiment, the first gate G1 may function as a mask during the process of doping the semiconductor pattern of the first transistor TR1. The second gate G2 may function as a mask during the process of doping the semiconductor pattern of the second transistor TR2.

The second insulating layer INS2 may cover the first and second gates G1 and G2 and be disposed on the first insulating layer INS1 (e.g., disposed directly thereon in the third direction DR3). The third insulating layer INS3 may be disposed on the second insulating layer INS2 (e.g., disposed directly thereon in the third direction DR3).

First and second connection electrodes CNE1-1 and CNE2-1 may be disposed on the third insulating layer INS3 (e.g., disposed directly thereon in the third direction DR3). In an embodiment, the first connection electrode CNE1-1 may be connected to (e.g., directly connected thereto) the first drain D1 via a first contact hole CH1-1 passing through the first to third insulating layers INS1 to INS3. The second connection electrode CNE2-1 may be connected to (e.g., directly connected thereto) the second drain D2 via a second contact hole CH2-1 passing through the first to third insulating layers INS1 to INS3. The fourth insulating layer INS4 may cover the first and second connection electrodes CNE1-1 and CNE2-1, and be disposed on the third insulating layer INS3 (e.g., disposed directly thereon in the third direction DR3). The fifth insulating layer INS5 may be disposed on the fourth insulating layer INS4 (e.g., disposed directly thereon in the third direction DR3).

Third and fourth connection electrodes CNE1-2 and CNE2-2 may be disposed on the fifth insulating layer INS5 (e.g., disposed directly thereon in the third direction DR3). In an embodiment, the third connection electrode CNE1-2 may be connected to (e.g., directly connected thereto) the first connection electrode CNE1-1 via a third contact hole CH1-2 passing through the fourth and fifth insulating layers INS4 and INS5. The fourth connection electrode CNE2-2 may be connected to (e.g., directly connected thereto) the second connection electrode CNE2-1 via a fourth contact hole CH2-2 passing through the fourth and fifth insulating layers INS4 and INS5. The sixth insulating layer INS6 may cover the third and fourth connection electrodes CNE1-2 and CNE2-2, and be disposed on the fifth insulating layer INS5 (e.g., disposed directly thereon in the third direction DR3).

The first to sixth insulating layers INS1 to INS6 may each include an inorganic insulating layer or an organic insulating layer. For example, in an embodiment the inorganic insulating layer may include at least one of aluminum oxide, titanium oxide, silicon oxide, silicon oxynitride, zirconium oxide, or hafnium oxide. The organic insulating layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The first lower electrode EL1-B1 may be disposed on the sixth insulating layer INS6 (e.g., disposed directly thereon in the third direction DR3). In an embodiment, the first lower electrode EL1-B1 may be connected to (e.g., directly connected thereto) the third connection electrode CNE1-2 via a fifth contact hole CH1-3 passing through the sixth insulating layer INS6. The first lower electrode EL1-B1 may be electrically connected to the first drain D1 of the transistor TR1 via the first and third connection electrodes CNE1-1 and CNE1-2.

Fifth and sixth connection electrodes CNE2-3 and CNE2-4 may be further disposed on the circuit layer DP-CL. In an embodiment, seventh and eighth contact holes CH2-4 and CH2-5 passing through the organic layer BV may be defined in the organic layer BV. The seventh and eighth contact holes CH2-4 and CH2-5 may electrically connect the second transistor TR2 and the second light-emitting element ED-B2.

The fifth connection electrode CNE2-3 may be disposed on the sixth insulating layer INS6 (e.g., disposed directly thereon in the third direction DR3). In an embodiment, the fifth connection electrode CNE2-3 may be connected to (e.g., directly connected thereto) the fourth connection electrode CNE2-2 via a sixth contact hole CH2-3 passing through the sixth insulating layer INS6. The first sub-organic layer BV-S1 may cover the fifth connection electrode CNE2-3 and be disposed on the sixth insulating layer INS6 (e.g., disposed directly thereon in the third direction DR3). The sixth connection electrode CNE2-4 may be disposed on the first sub-organic layer BV-S1 (e.g., disposed directly thereon in the third direction DR3). In an embodiment, the sixth connection electrode CNE2-4 may be connected to (e.g., directly connected thereto) the fifth connection electrode CNE2-3 via a seventh contact hole CH2-4 passing through the first sub-organic layer BV-S1.

The second sub-organic layer BV-S2 may cover the sixth connection electrode CNE2-4 and be disposed on the first sub-organic layer BV-S1 (e.g., disposed directly thereon in the third direction DR3). The second lower electrode EL1-B2 may be disposed on the second sub-organic layer BV-S2 (e.g., disposed directly thereon in the third direction DR3). In an embodiment, the second lower electrode EL1-B2 may be connected to (e.g., directly connected thereto) the sixth connection electrode CNE2-4 via an eighth contact hole CH2-5 passing through the second sub-organic layer BV-S2. The second lower electrode EL1-B2 may be electrically connected to the second drain D2 of the second transistor TR2 via the second connection electrode CNE2-1, and the fourth to sixth connection electrodes CNE2-2, CNE2-3, CNE2-4.

In an embodiment, the organic layer BV may include an organic material which is the same as that of at least one among the first to sixth insulating layers INS1 to INS6. For example, the organic layer BV may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The organic layer BV may not overlap the first light-emitting layer EML-B1 of the first light-emitting element ED-B1 (e.g., in the third direction DR3), and may overlap the second light-emitting layer EML-B2 of the second light-emitting element ED-B2 (e.g., in the third direction DR3). The first shortest distance DT1 from the circuit layer DP-CL to the first light-emitting layer EML-B1 may be less than the second shortest distance DT2 from the circuit layer DP-CL to the second light-emitting layer EML-B2. The first shortest distance DT1 and the second shortest distance DT2 may be distances parallel to the thickness direction DR3. As illustrated above, since in the thickness direction DR3, the second light-emitting element ED-B2 is disposed at a relatively higher position than the first light-emitting element ED-B1, the second shortest distance DT2 may be greater than the first shortest distance DT1.

The first shortest distance DT1 may be a distance (e.g., in the third direction DR3) from an upper surface of the circuit layer DP-CL to a lower surface of the first light-emitting layer EML-B1. The second shortest distance DT2 may be a distance (e.g., in the third direction DR3) from the upper surface of the circuit layer DP-CL to a lower surface of the second light-emitting layer EML-B2. The upper surface of the circuit layer DP-CL may be adjacent to the display element layer DP-ED (e.g., in a direction opposite to the third direction DR3), and a lower surface of the circuit layer DP-CL may be adjacent to the base layer BS (e.g., in the third direction DR3). In the circuit layer DP-CL, the upper surface and the lower surface may face each other in the thickness direction DR3. The lower surface of the first light-emitting layer EML-B1 may be adjacent to the first lower electrode EL1-B1 (e.g., in the third direction DR3), and an upper surface of the first light-emitting layer EML-B1 may be adjacent to the first upper electrode EL2 (e.g., in a direction opposite to the third direction DR3). In the first light-emitting layer EML-B1, the upper surface and the lower surface may face each other in the thickness direction DR3. The lower surface of the second light-emitting layer EML-B2 may be adjacent to the second lower electrode EL1-B2 (e.g., in the third direction DR3), and an upper surface of the second light-emitting layer EML-B2 may be adjacent to the second upper electrode EL2 (e.g., in a direction opposite to the third direction DR3). In the second light-emitting layer EML-B2, the upper surface and the lower surface may face each other in the thickness direction DR3.

In an embodiment, in the organic layer BV, a first organic opening B-OH1 may be defined in the first sub-organic layer BV-S1, and a second organic opening B-OH2 may be defined in the second sub-organic layer BV-S2. The first organic opening B-OH1 and the second organic opening B-OH2 may overlap the first pixel opening P-OH1 (e.g., in a plan view). The first organic opening B-OH1 and the second organic opening B-OH2 may not overlap the second pixel opening P-OH2 (e.g., in a plan view). In the first direction DR1 perpendicular to the thickness direction DR3, the second width WT2 of the second organic opening B-OH2 may be greater than or equal to the first width WT1 of the first organic opening B-OH1. For example, the second width WT2 of the second organic opening B-OH2 may be greater than the first width WT1 of the first organic opening B-OH1.

In the encapsulation layer TFE, a lower surface and an upper surface may not be flat. The encapsulation layer TFE may have a non-uniform thickness. In the encapsulation layer TFE, the thickness of the first region overlapping the light-emitting element which is disposed on the same layer as the organic layer BV may be different from the thickness of the second region overlapping the light-emitting element which is disposed on the organic layer BV. For example, in the encapsulation layer TFE, the thickness (e.g., length in the third direction DR3) of the first region overlapping the first light-emitting element ED-B1 may be different from the thickness (e.g., length in the third direction DR3) of the second region overlapping the second light-emitting element ED-B2. The thickness of the first region overlapping the first light-emitting element ED-B1 may be greater than the thickness of the second region overlapping the second light-emitting element ED-B2.

The description of the circuit layer DP-CL and the organic layer BV described in FIG. 5 may be similarly applied to the circuit layer DP-CL and the organic layer BV illustrated in FIG. 4. Additionally, the description of the first light-emitting element ED-B1 described in FIG. 5 may be similarly applied to the third light-emitting element ED-G1 illustrated in FIG. 4. The description of the second light-emitting element ED-B2 described in FIG. 5 may be similarly applied to the fourth light-emitting element ED-G2 illustrated in FIG. 4.

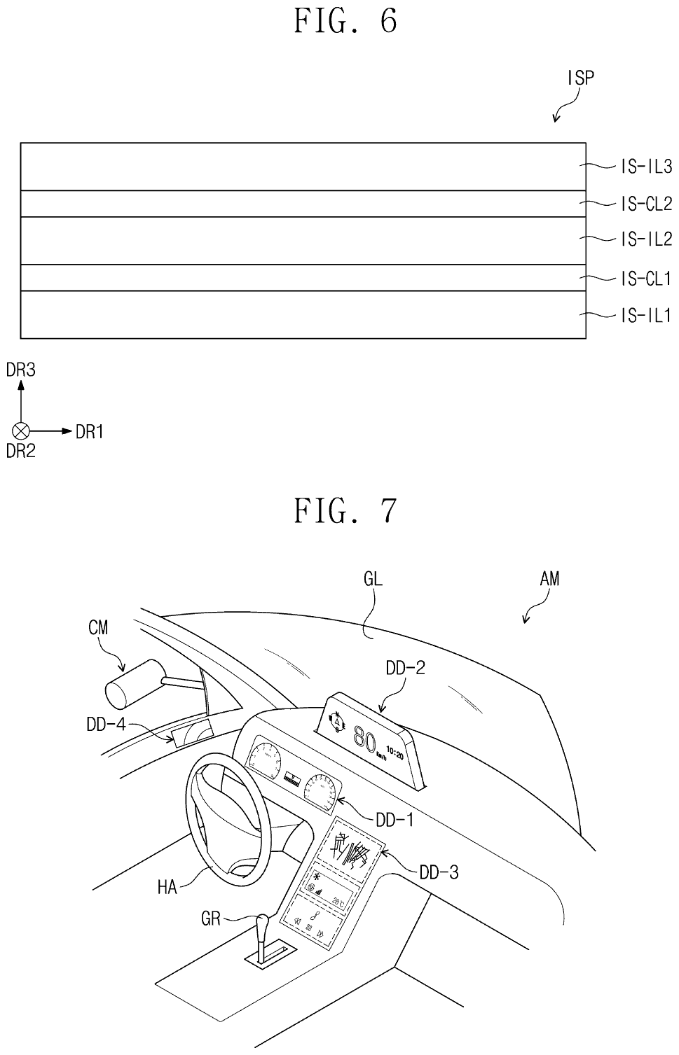

FIG. 6 may be a cross-sectional view illustrating, in detail, an input-sensing layer ISP. However, this is presented as an example, and a configuration of the input-sensing layer ISP is not necessarily limited thereto.

Referring to FIG. 6, in an embodiment the input-sensing layer ISP may include a first sensing-insulating layer IS-IL1, a second sensing-insulating layer IS-IL2, and a third sensing-insulating layer IS-IL3. The input-sensing layer ISP may include at least one conductive layer disposed on the sensing-insulating layers. For example, in an embodiment the input-sensing layer ISP may include a first conductive layer IS-CL1 and a second conductive layer IS-CL2.

The first sensing-insulating layer IS-IL1 may be disposed on the encapsulation layer TFE (see FIG. 4). The first sensing-insulating layer IS-IL1 may include at least one inorganic insulating layer. The first sensing-insulating layer IS-IL1 may be connected to the encapsulation layer TFE (see FIG. 4). Alternatively, in an embodiment the first sensing-insulating layer IS-IL1 may be omitted, and in this embodiment, the first conductive layer IS-CL1 may be connected to the encapsulation layer TFE (see FIG. 4).

The first conductive layer IS-CL1 may be disposed on the first sensing-insulating layer IS-IL1 (e.g., disposed directly thereon in the third direction DR3). In an embodiment, the first conductive layer IS-CL1 may include a plurality of first conductive patterns. The plurality of first conductive patterns may be disposed on the first sensing-insulating layer IS-IL1. The second sensing-insulating layer IS-IL2 may be disposed on the first sensing-insulating layer IS-IL1.

The second conductive layer IS-CL2 may be disposed on the second sensing-insulating layer IS-IL2 (e.g., disposed directly thereon in the third direction DR3). In an embodiment, the second conductive layer IS-CL2 may include a plurality of second conductive patterns. The plurality of second conductive patterns may be disposed on the second sensing-insulating layer IS-IL2. In an embodiment, the plurality of first conductive patterns of the first conductive layer IS-CL1 and the plurality of second conductive patterns of the second conductive layer IS-CL2 may each correspond to a mesh pattern.

The third sensing-insulating layer IS-IL3 may be disposed on the second sensing-insulating layer IS-IL2. The second sensing-insulating layer IS-IL2 and the third sensing-insulating layer IS-IL3 may each include an inorganic insulating layer or an organic insulating layer.

The first conductive layer IS-CL1 and the second conductive layer IS-CL2 may each have a single-layered structure or a multi-layered structure in which layers are stacked along the thickness direction DR3. The conductive layers IS-CL1 and IS-CL2 having a single-layered structure may each include a metal layer or a transparent conductive layer. In an embodiment, the metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). Also, the transparent conductive layer may include a conductive polymer such as PEDOT, a metal nanowire, graphene, etc.

The conductive layers IS-CL1 and IS-CL2 having a multi-layered structure may include metal layers. For example, in an embodiment the metal layers may have a three-layered structure of titanium (Ti)/aluminum (Al)/titanium (Ti). The conductive layers IS-CL1 and IS-CL2 having a multi-layered structure may include at least one metal layer and at least one transparent conductive layer.

FIG. 7 is a view illustrating a vehicle AM in which first to fourth display devices DD-1, DD-2, DD-3, and DD-4 are disposed. At least one among the first to fourth display devices DD-1, DD-2, DD-3, and DD-4 may similarly include components of the display device DD, according to an embodiment, described with reference to FIGS. 1 to 6.

FIG. 7 illustrates that the vehicle AM is a car, but this is presented as an example and embodiments of the present disclosure are not necessarily limited thereto. For example, in some embodiments the first to fourth display devices DD-1, DD-2, DD-3, and DD-4 may also be disposed in other transportation means such as a bicycle, a motorcycle, a train, a ship, an airplane, etc. Additionally, at least one among the first to fourth display devices DD-1, DD-2, DD-3, and DD-4 which similarly include components of the display device DD according to an embodiment may be employed to a personal computer, a laptop computer, a personal digital terminal, a game console, a portable electronic device, a television, a monitor, an outdoor billboard, etc. Also, these are merely presented as examples, and the display device may be employed to other electronic apparatuses without departing from the spirit of embodiments of the present inventive concept.

Referring to FIG. 7, the vehicle AM may include a steering wheel HA and a gear GR for operating the vehicle AM, and have a windshield GL disposed toward a driver.

The first display device DD-1 may be disposed in a first region overlapping or disposed adjacent to the steering wheel HA. For example, the first display device DD-1 may be a digital cluster which displays first information of the vehicle AM. In an embodiment, the first information may include a first scale which indicates a driving speed of the vehicle AM, a second scale which indicates a rotation speed of an engine (e.g., revolutions per minute (RPM)), and an image which indicates a fuel condition. However, embodiments of the present disclosure are not necessarily limited thereto. The first scale and the second scale may be represented as digital images.

The second display device DD-2 may be disposed in a second region which faces a driver's seat and overlaps the windshield GL. The driver's seat may be a seat near which the steering wheel HA is disposed. For example, the second display device DD-2 may be a head up display (HUD) which displays second information of the vehicle AM. The second display device DD-2 may be an optically transparent device. In an embodiment, the second information may include a digital number which indicates a driving speed of the vehicle AM, and further include information such as a current time. In some embodiments, the second information of the second display device DD-2 may also be projected onto the windshield GL to be displayed.

The third display device DD-3 may be disposed in a third region adjacent to the gear GR. For example, the third display device DD-3 may be a center information display (CID) for a vehicle which is disposed between a driver's seat and a passenger seat and displays third information. The passenger seat may be a seat spaced apart from the driver's seat with the gear GR therebetween. In an embodiment, the third information may include information about a road condition (e.g., navigation information), music or radio playing, dynamic image playing, a temperature inside the vehicle AM, etc. However, embodiments of the present disclosure are not necessarily limited thereto.

The fourth display device DD-4 may be disposed in a fourth region which is spaced apart from the steering wheel HA and the gear GR and is adjacent to a side portion of the vehicle AM. For example, the fourth display device DD-4 may be a digital side-view mirror which displays fourth information. In an embodiment, the fourth display device DD-4 may display an exterior image from the vehicle AM captured by a camera module CM disposed outside the vehicle AM. The fourth information may include an external image from the vehicle AM. However, embodiments of the present disclosure are not necessarily limited thereto.

The first to fourth information described above is presented as examples, and the first to fourth display devices DD-1, DD-2, DD-3, and DD-4 may further include information about an interior and an exterior of the vehicle. The first to fourth information may include different information. However, embodiments of the present inventive concept are not necessarily limited thereto, and some pieces of the first to fourth information may include the same information as each other.

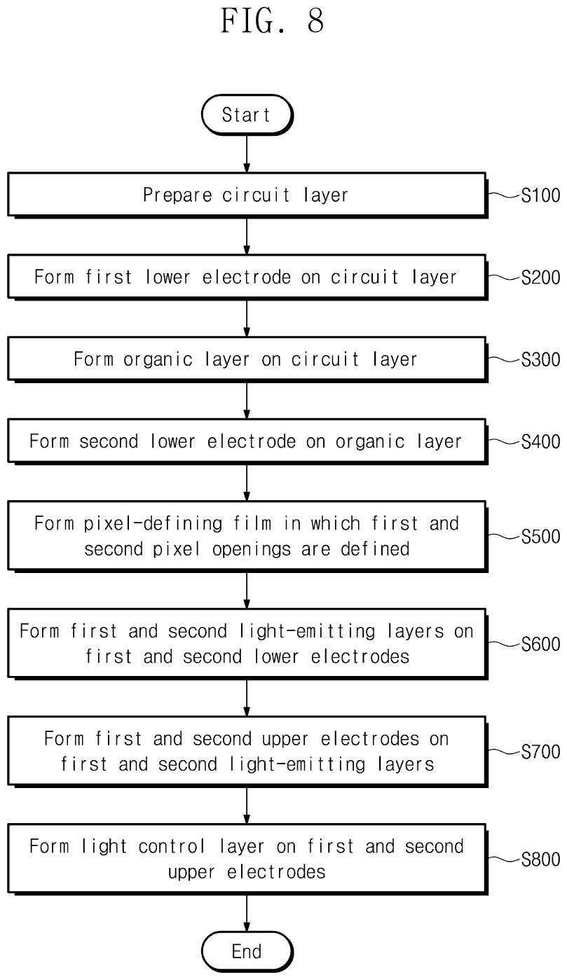

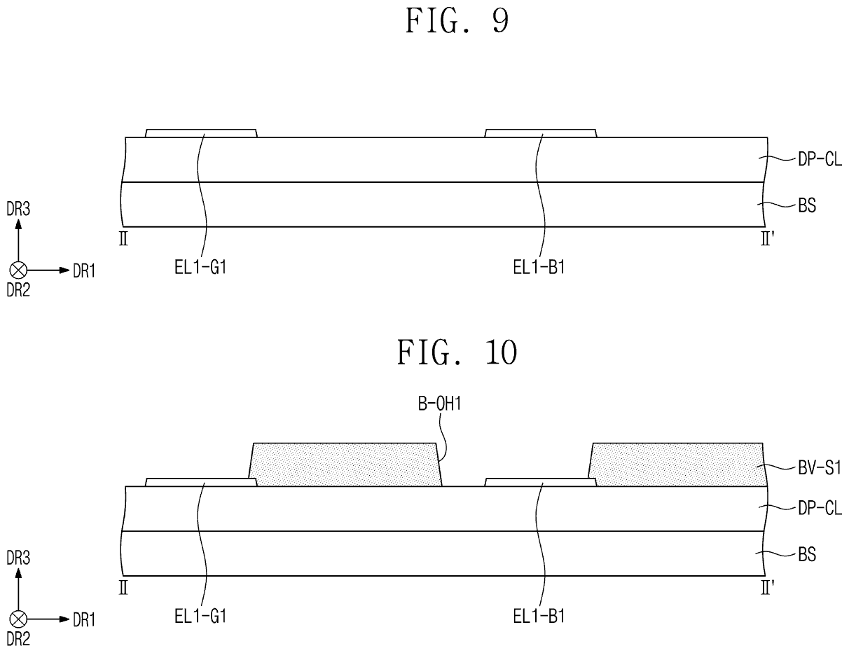

A display device according to an embodiment may be formed through a manufacturing method for a display device according to an embodiment. FIG. 8 is a flowchart showing a manufacturing method for a display device according to an embodiment. FIGS. 9 to 15 are views schematically illustrating display device manufacturing steps according to embodiments. Hereinafter, with regard to the descriptions of FIGS. 8 to 15, the contents duplicated with those described with the references to FIGS. 1 to 7 may not be explained again for economy of explanation, and the following description will be mainly focused on the differences.

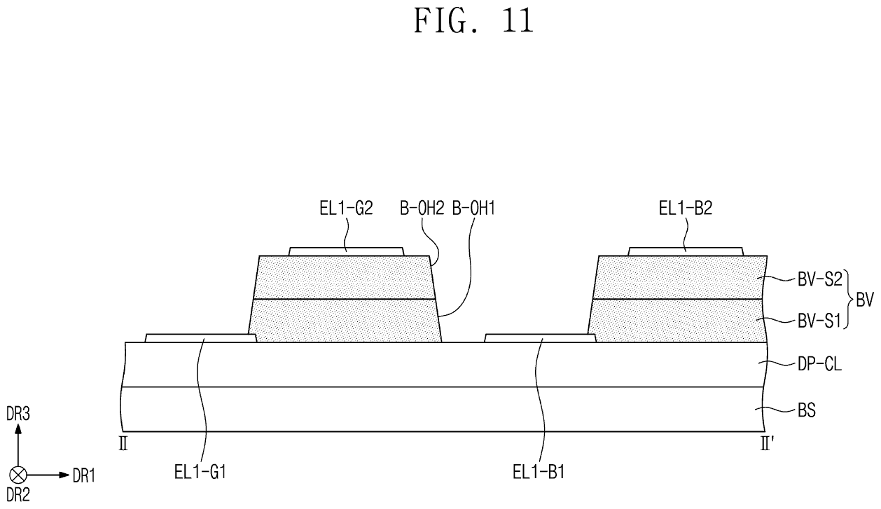

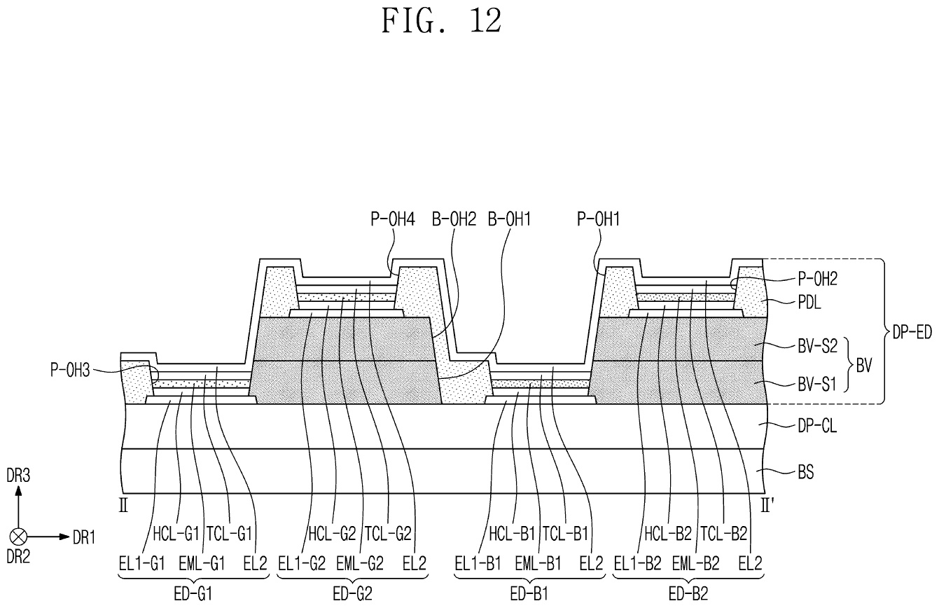

Referring to FIG. 8, the manufacturing method for the display device according to an embodiment may include steps of: preparing a circuit layer in block S100, forming a first lower electrode on the circuit layer in block S200, forming an organic layer on the circuit layer in block S300, forming a second lower electrode on the organic layer in block S400, forming a pixel-defining film in which first and second pixel openings are defined in block S500, forming first and second light-emitting layers on the first and second lower electrodes in block S600, forming first and second upper electrodes on the first and second light-emitting layers in block S700, and forming a light control layer on the first and second upper electrodes in block S800. In an embodiment, the step of forming an organic layer BV (see FIG. 11) may be performed between a step of forming a first lower electrode EL1-B1 (see FIG. 9) and a step of forming a second lower electrode EL1-B2 (see FIG. 11) (S400). The organic layer BV (see FIG. 12) may be formed between a circuit layer DP-CL (see FIG. 12) and a pixel-defining film PDL (see FIG. 12). Accordingly, the display device DD (see FIG. 4) manufactured through the manufacturing method for the display device according to an embodiment may exhibit excellent display quality.

Referring to FIGS. 9 and 10, first and third lower electrodes EL1-B1 and EL1-G1 may be formed on the circuit layer DP-CL (e.g., formed directly thereon in the third direction DR3). As illustrated with reference to FIG. 5, in an embodiment the circuit layer DP-CL may include the transistors TR1 and TR2 (see FIG. 5), the insulating layers BFL, and INS1 to INS6 (see FIG. 5), and the connection electrodes CNE1-1, CNE1-2, CNE2-1, and CNE2-2 (see FIG. 5). The contact holes CH1-1, CH1-2, CH1-3, CH2-1, CH2-2, and CH2-3 (see FIG. 5) may be formed in the circuit layer DP-CL.

The first and third lower electrodes EL1-B1 and EL1-G1 are formed, and then a first sub-organic layer BV-S1 may be formed on the circuit layer DP-CL (e.g., formed directly thereon in the third direction DR3). In an embodiment, a first organic opening B-OH1 may be formed in the first sub-organic layer BV-S1. The first and third lower electrodes EL1-B1 and EL1-G1 may be exposed in the first organic opening B-OH1.

Referring to FIG. 11, a second sub-organic layer BV-S2 may be formed on the first sub-organic layer BV-S1 (e.g., formed directly thereon in the third direction DR3), and second and fourth lower electrodes EL1-B2 and EL1-G2 may be formed on the second sub-organic layer BV-S2. For example, the second and fourth lower electrodes EL1-B2 and EL1-G2 may be directly formed on the second sub-organic layer BV-S2 (e.g., in the third direction DR3). In an embodiment, a second organic opening B-OH2 may be formed in the second sub-organic layer BV-S2. The second organic opening B-OH2 may overlap the first organic opening B-OH1 (e.g., in the third direction DR3). The organic layer BV may include the first and second sub-organic layers BV-S1 and BV-S2, and be formed on the circuit layer DP-CL.

Referring to FIG. 12, the pixel-defining films PDL may be formed on the first to fourth lower electrodes EL1-B1, EL1-B2, EL1-G1, and EL1-G2. First to fourth pixel openings P-OH1, P-OH2, P-OH3, and P-OH4 respectively exposing the first to fourth lower electrodes EL1-B1, EL1-B2, EL1-G1, and EL1-G2 may be formed in the pixel-defining films PDL. Thereafter, first to fourth hole control layers HCL-B1, HCL-B2, HCL-G1, and HCL-G2, first to fourth light-emitting layers EML-B1, EML-B2, EML-G1, and EML-G2, first to fourth electron control layers TCL-B1, TCL-B2, TCL-G1, and TCL-G2, an upper electrode EL2 may be sequentially formed on the first to fourth lower electrodes EL1-B1, EL1-B2, EL1-G1, and EL1-G2. Finally, first to fourth light-emitting elements ED-B1, ED-B2, ED-G1, and ED-G2 may be formed. However, embodiments of the present disclosure are not necessarily limited thereto. For example, in an embodiment at least one among the first to fourth hole control layers HCL-B1, HCL-B2, HCL-G1, and HCL-G2, and the first to fourth electron control layers TCL-B1, TCL-B2, TCL-G1, and TCL-G2 may be omitted.

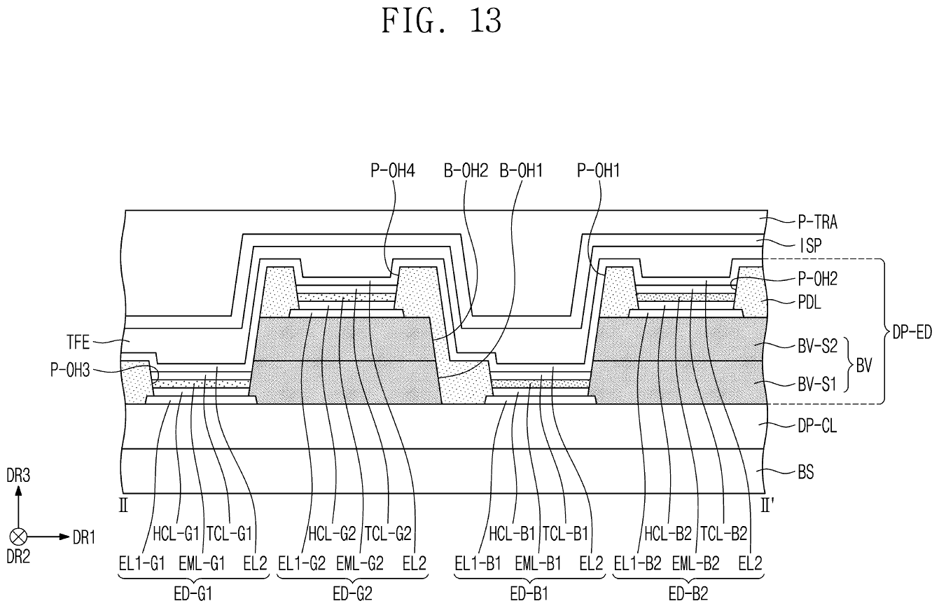

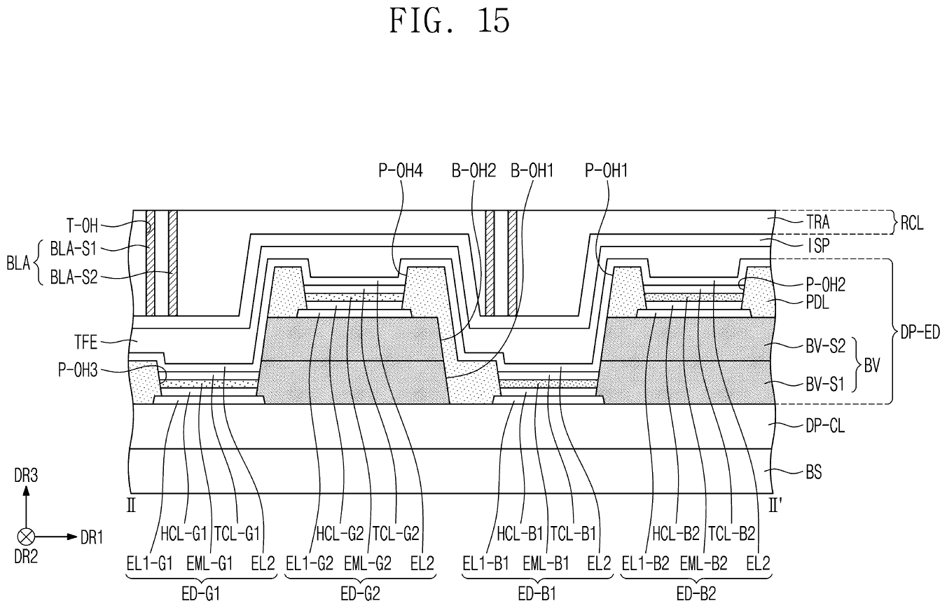

Referring to FIG. 13, in an embodiment a preliminary transmission part P-TRA may be formed on a display element layer DP-ED including first to fourth light-emitting elements ED-B1, ED-B2, ED-G1, and ED-G2, organic layers BV, and pixel-defining films PDL. Before the preliminary transmission part P-TRA is formed, an encapsulation layer TFE and an input-sensing layer ISP may be sequentially formed on the display element layer DP-ED (e.g., in the third direction DR3). In an embodiment, a transmission part TRA (see FIG. 15) of a light control layer RCL (see FIG. 15) may be formed from the preliminary transmission part P-TRA. The preliminary transmission part P-TRA may include an optically transparent material. For example, in an embodiment the preliminary transmission part P-TRA may include at least one of a polyimide-based resin, an acryl-based resin, or a siloxane-based resin. The preliminary transmission part P-TRA may be a planarization layer.

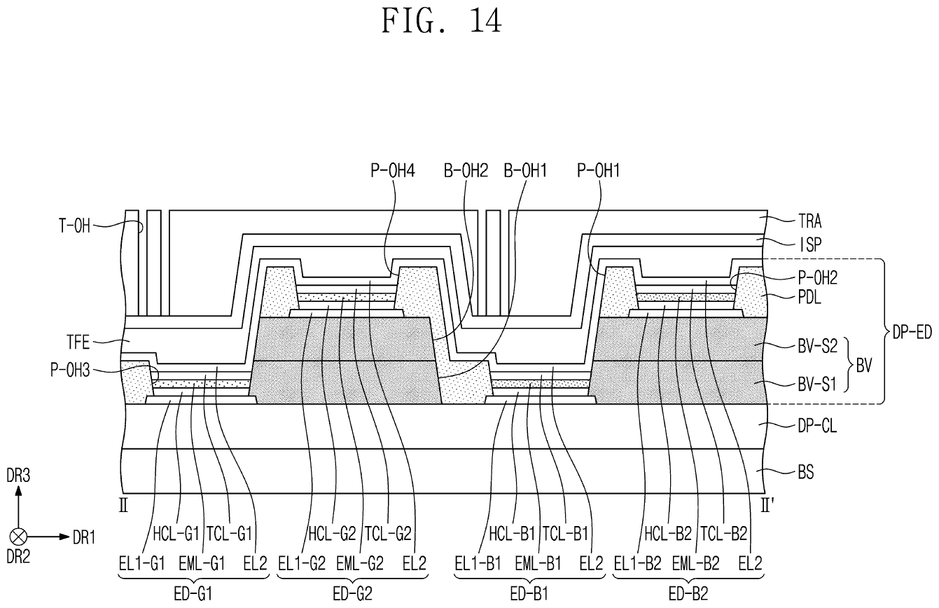

Referring to FIG. 14, an opening T-OH may be formed in a preliminary transmission part P-TRA. For example, in an embodiment the opening T-OH may be formed in the preliminary transmission part P-TRA through a dry etching process.

A material (hereinafter, referred to as a light blocking material) from which the light blocking part BLA (see FIG. 15) is formed may be provided to the opening T-OH. The light blocking material may be provided so as to fill the opening T-OH and overlap the entire of the preliminary transmission part P-TRA in which the opening T-OH is formed. For example, the light blocking material may fill the opening T-OH and also be provided on (e.g., disposed directly thereon) an upper surface of the preliminary transmission part P-TRA. Subsequently, the light blocking material provided on the upper surface of the preliminary transmission part P-TRA is removed, and as illustrated in FIG. 15, a light blocking part BLA may be formed.

A display device according to an embodiment may include an organic layer disposed between a circuit layer and a pixel-defining film, and a light control layer including a light blocking part which is disposed to fill an opening defined in a transmission part. The organic layer may only overlap either of a first light-emitting element or a second light-emitting element which emits light having the same color as each other. The first light-emitting element may be disposed on the same layer as the organic layer, and the second light-emitting element may be disposed on the organic layer. Accordingly, in the first light-emitting element and the second light-emitting element which emit light having the same color, the second light-emitting element is disposed at a relatively higher position in a thickness direction, and thus it is possible to minimize (or prevent) luminance degradation due to the light blocking part in a second mode. Accordingly, the display device according to an embodiment of the present inventive concept may exhibit excellent display quality.

A display device according to an embodiment includes an organic layer disposed between a circuit layer and a pixel-defining film, thereby exhibiting excellent display quality.

A manufacturing method for a display device according to an embodiment includes a step of forming an organic layer between a step of forming a circuit layer and a step of forming a pixel-defining film, through which a display device with excellent display quality may be manufactured.

Although embodiments of the present inventive concept have been described, it is understood that the present inventive concept should not be limited to these embodiments but various changes and modifications can be made by one ordinary skilled in the art within the spirit and scope of the present inventive concept.

Therefore, the technical scope of the present inventive concept is not limited to the contents described in the detailed description of the specification.

What is claimed is:

1. An electronic device, comprising:
a display device; and
a power supply providing power to the display device,
wherein the display device comprises:
a circuit layer including a transistor, and at least one insulating layer disposed on the transistor;
a display element layer disposed on the circuit layer, the display element layer including a first light-emitting element having a first light-emitting layer, a second light-emitting element having a second light-emitting layer, the second light-emitting element is spaced apart from the first light-emitting element in a first direction perpendicular to a thickness direction of the display device, a pixel-defining film having a first pixel opening and a second pixel opening defined therein, and an organic layer disposed between the circuit layer and the pixel-defining film in the thickness direction of the display device; and
a light control layer disposed on the display element layer, the light control layer including a transmission part having an opening defined therein, and a light blocking part disposed to fill the opening and blocking light emitted by the display element layer, wherein the light blocking part overlaps the first light-emitting layer and does not overlap the second light-emitting layer;
the first light-emitting element is co-planar with the organic layer; and
the second light-emitting element is disposed above the organic layer.

2. The electronic device of claim 1, wherein:
the first light-emitting element is disposed directly above the circuit layer; and
the second light-emitting element is disposed directly above the organic layer.

3. The electronic device of claim 1, wherein the organic layer comprises:
a first sub-organic layer; and
a second sub-organic layer disposed on the first sub-organic layer.

4. The electronic device of claim 3, wherein:
the first sub-organic layer has a first organic opening defined therein;
the second sub-organic layer has a second organic opening defined therein; and
the first organic opening and the second organic opening each overlap the first pixel opening, and do not overlap the second pixel opening.

5. The electronic device of claim 4, wherein a second width of the second organic opening is greater than or equal to a first width of the first organic opening in the first direction.

6. The electronic device of claim 1, wherein the organic layer includes a contact hole defined therein, the contact hole connecting the second light-emitting element and the transistor.

7. The electronic device of claim 1, wherein the organic layer comprises an organic material that is a same material as a material of the at least one insulating layer.

8. The electronic device of claim 1, wherein:
in a first mode, the first light-emitting element emits light and the second light-emitting element does not emit light; and
in a second mode, the first light-emitting element does not emit light and the second light-emitting element emits light.

9. The electronic device of claim 1, wherein the light blocking part overlaps the first light-emitting layer, and does not overlap the second light-emitting layer.

10. The electronic device of claim 1, wherein:
the light blocking part comprises a first sub-light blocking part, and a second sub-light blocking part spaced apart from the first sub-light blocking part in the first direction;
the first sub-light blocking part overlaps the pixel-defining film,
the second sub-light blocking part overlaps the first light-emitting layer; and
the first sub-light blocking part and the second sub-light blocking part do not overlap the second light-emitting layer.

11. The electronic device of claim 1, wherein the first light-emitting element and the second light-emitting element emit light having a same color as each other.

12. The electronic device of claim 1, wherein the electronic device is a television, a monitor, an outdoor billboard, a tablet computer, a vehicle navigation unit, a personal computer, a laptop computer, a personal digital terminal, a game console, a smart phone, or a camera.

13. An electronic device, comprising a display device,
wherein the display device comprises:
a circuit layer including a transistor, and at least one insulating layer disposed on the transistor;
a display element layer disposed on the circuit layer, the display element layer including a first light-emitting element, a second light-emitting element spaced apart from the first light-emitting element in a first direction perpendicular to a thickness direction of the display device, a pixel-defining film having a first pixel opening and a second pixel opening defined therein, and an organic layer disposed between the circuit layer and the pixel-defining film in the thickness direction of the display device; and
a light control layer disposed on the display element layer, the light control layer including a transmission part having an opening defined therein, and a light blocking part disposed to fill the opening,
wherein the first light-emitting element includes a first lower electrode exposed in the first pixel opening, a first upper electrode disposed on the first lower electrode, and a first light-emitting layer disposed between the first lower electrode and the first upper electrode,
the second light-emitting element includes a second lower electrode exposed in the second pixel opening, a second upper electrode disposed on the second lower electrode, and a second light-emitting layer disposed between the second lower electrode and the second upper electrode, and
in the thickness direction of the display device, a first shortest distance from the circuit layer to the first light-emitting layer is less than a second shortest distance from the circuit layer to the second light-emitting layer.

14. The electronic device of claim 13, wherein the first light-emitting element is disposed on a same layer as the organic layer, and
the second light-emitting element is disposed above the organic layer.

15. The electronic device of claim 13, wherein the organic layer does not overlap the first light-emitting layer, and overlaps the second light-emitting layer.

16. The electronic device of claim 13, wherein:
the organic layer has an organic opening defined therein; and
the organic opening overlaps the first pixel opening, and does not overlap the second pixel opening.

17. The electronic device of claim 13, wherein the organic layer includes a contact hole defined therein, the contact hole connecting the second light-emitting element and the transistor.

18. The electronic device of claim 13, wherein:
in a first mode, the first light-emitting element emits light and the second light-emitting element does not emit light; and
in a second mode, the first light-emitting element does not emit light and the second light-emitting element emits light.

19. The electronic device of claim 13, wherein the light blocking part overlaps the first light-emitting element, and does not overlap the second light-emitting element.

20. A method for manufacturing an electronic device, the method for manufacturing the electronic device comprising a method for manufacturing an display device:
the method for manufacturing the display device comprises:
preparing a circuit layer including a transistor and at least one insulating layer disposed on the transistor;
forming a first lower electrode on the circuit layer;
forming an organic layer on the circuit layer;
forming a second lower electrode above the organic layer;
forming a pixel-defining film having a first pixel opening and a second pixel opening defined therein, the first pixel opening exposing the first lower electrode and the second pixel opening exposing the second lower electrode;
forming a first light-emitting layer on the first lower electrode, and forming a second light-emitting layer on the second lower electrode;
forming a first upper electrode on the first light-emitting layer, and forming a second upper electrode on the second light-emitting layer; and
forming, on the first upper electrode and the second upper electrode, a light control layer including a transmission part having an opening defined therein, and a light blocking part disposed to fill the opening,
wherein the organic layer is formed between the circuit layer and the pixel-defining film in a thickness direction of the display device.
